(19) United States
(12) Patent Application Publication
(10) Pub. No.: US 2026/0052738 A1
(43) Pub. Date: Feb. 19, 2026

(54) POWER SEMICONDUCTOR DEVICES AND METHODS OF FORMING THE SAME

(71) Applicant: Wolfspeed, Inc., Durham, NC (US)

(72) Inventors: Woongsun Kim, Cary, NC (US); Rahul R. Potera, Apex, NC (US); Naeem Islam, Fuquay-Varina, NC (US); Madankumar Sampath, Morrisville, NC (US); Sei-Hyung Ryu, Cary, NC (US)

(21) Appl. No.: 18/804,575

(22) Filed: Aug. 14, 2024

(51) Int. Cl. H01L 29/808; H01L 27/098; H01L 29/06; H01L 29/10; H01L 29/16; H01L 29/423

(52) U.S. Cl. CPC H10D 30/831; H10D 62/107; H10D 62/343; H10D 64/513; H10D 84/87; H10D 62/8325

(57) ABSTRACT

Semiconductor devices are provided that comprise a semiconductor layer structure that comprises a drift region having a first conductivity type and a gate junction region having a second conductivity type, and a gate trench in the semiconductor layer structure. At least a portion of the gate junction region that is on a sidewall of the gate trench may have a tapered shape in a cross-sectional view.

### TECHNICAL FIELD

The present disclosure relates to semiconductor devices and, more particularly, to power semiconductor devices such as junction field effect transistors, which are commonly referred to as “JFETs.”

### BACKGROUND OF THE INVENTION

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. Silicon carbide-based power semiconductor devices typically have a substrate (e.g., a silicon carbide wafer) having a first conductivity type (e.g., an n-type substrate), on which a silicon carbide epitaxial layer structure is formed. Herein, the combination of any substrate (since the substrate may later be removed) and the epitaxial layers is referred to as a semiconductor layer structure. The semiconductor layer structure may have both first and second conductivity type layers and/or regions. Herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means that either the first region has n-type conductivity and the second region has p-type conductivity or, alternatively, that the first region has p-type conductivity and the second region has n-type conductivity.

The epitaxial layer structure of most power semiconductor devices includes an active region and an inactive region. The active region is the portion of the device that acts as a main junction for blocking voltage during off-state operation (also referred to as “reverse bias” or “reverse blocking” operation) and is also the portion of the device through which current flows during on-state operation (also referred to as “forward bias” operation). The inactive region may include, for example, a gate region and/or an edge termination region. The gate region may include some or all of the portion of the epitaxial layer structure that is underneath a gate pad of the device, as well as portions of the epitaxial layer structure that are underneath any gate buses. The edge termination region is a portion of the epitaxial layer structure that at least partially surrounds the active region. The edge termination region is designed to spread the electric fields during reverse blocking operation out over a greater area in order to reduce electric field crowding effects that may otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A power JFET, for example, is a three terminal device that has gate, drain and source terminals that are formed on a semiconductor layer structure. Source regions that are electrically connected to the source terminal and a drain region that is electrically connected to the drain terminal may be formed in the semiconductor layer structure. A plurality of channel regions are interposed in the semiconductor layer structure between the source regions and the drain region. The width, and hence the conductivity, of the channel regions may be controlled by an electric field where the electric field is controlled by a bias voltage that is applied between the gate and source terminals. Accordingly, a power JFET can be switched between its on and off states by applying appropriate voltages to the gate terminal thereof.

A gate structure of the power JFET may include, for example, a gate bond pad that serves as the gate terminal, an optional gate pad that is underneath and electrically connected to the gate bond pad, and one or more gate buses that distribute gate signals from the gate pad to gate electrodes that extend throughout the active region of the JFET.

Power JFETs are typically normally-on devices, meaning that a JFET typically can conduct current when a voltage of 0 volts is applied to the gate structure (i.e., when the gate-to-source voltage V_{GS} is zero). In order to convert a silicon carbide-based power JFET from a normally-on device to a normally-off device, a low-power MOSFET (which is typically an inexpensive silicon-based MOSFET) may be coupled to the power JFET in a cascode configuration to form an integrated normally-off JFET switch. FIG. 1 is a circuit diagram of such an integrated normally-off JFET switch 1 that includes a high-power JFET 10 cascoded with a low-power normally-off MOSFET 30. As shown in FIG. 1, the gate terminal G_{MOS} of the MOSFET 30 acts as the gate terminal G_{SW} of the switch 1, the source terminal S_{MOS} of the MOSFET 30 acts as the source terminal S_{SW} of the switch 1, and the drain terminal D_{JFET} of the JFET 10 acts as the drain terminal D_{SW} of the switch 1. The source terminal S_{JFET} of the JFET 10 is coupled to the drain terminal D_{MOS} of the MOSFET 30, and the gate terminal G_{JFET} of the JFET 10 is coupled to the source terminal S_{MOS} of the MOSFET 30. When the MOSFET 30 is turned off, the drain terminal D_{MOS} of the MOSFET 30, and hence the source terminal S_{JFET} of the JFET 10, may be at a large positive voltage, which would mean that the gate terminal G_{JFET} of the JFET 10 relative to the source terminal S_{JFET} of the JFET 10 may be at a large negative voltage (e.g., −30 volts). This large negative voltage acts to keep the JFET 10 from conducting. When the MOSFET 30 is turned on, the drain terminal D_{MOS} of the MOSFET 30, and hence the source terminal S_{JFET} of the JFET 10, may be at a voltage of near zero, allowing the JFET 10 to turn on. Thus, the integrated normally-off JFET switch 1 of FIG. 1 will operate as a normally-off device that turns on by applying a voltage to the gate terminal G_{MOS} of the MOSFET 30 that exceeds a threshold voltage of the MOSFET 30.

### SUMMARY OF THE INVENTION

Pursuant to aspects of the present disclosure, a semiconductor device is provided that comprises a semiconductor layer structure that comprises a drift region having a first conductivity type and a gate junction region having a second conductivity type, and a gate trench in the semiconductor layer structure. At least a portion of the gate junction region that is on a sidewall of the gate trench has a tapered shape in a cross-sectional view.

In some embodiments, the gate junction region extends underneath the gate trench.

In some embodiments, the gate trench extends in a longitudinal direction in the semiconductor layer structure, and the gate junction region extends on the sidewall of the gate trench in the longitudinal direction.

In some embodiments, the portion of the gate junction region has a width in a transverse direction intersecting the longitudinal direction, and the width of the portion of the gate junction region increases with increasing depth in the semiconductor layer structure.

In some embodiments, the semiconductor layer structure further comprises a gate contact region underneath the gate trench and having the second conductivity type.

In some embodiments, the gate contact region has a higher second conductivity type doping concentration than the gate junction region.

In some embodiments, the gate junction region is on sidewalls of the gate contact region.

In some embodiments, the gate junction region extends underneath the gate contact region.

In some embodiments, the semiconductor device further comprises a gate electrode in the gate trench and on the gate contact region.

In some embodiments, the gate contact region electrically connects the gate electrode to the gate junction region.

In some embodiments, the gate contact region is between the gate electrode and the gate junction region.

In some embodiments, the semiconductor device further comprises a spacer in the gate trench between the gate electrode and the semiconductor layer structure.

In some embodiments, the semiconductor layer structure further comprises a channel region having the first conductivity type on the drift region and a source region having the first conductivity type on the channel region.

In some embodiments, an upper portion of the channel region has a higher first conductivity type doping concentration than a lower portion of the channel region.

In some embodiments, the gate junction region is a first gate junction region, the semiconductor layer structure further comprises a second gate junction region adjacent the first gate junction region, and at least a portion of the channel region between the first gate junction region and the second gate junction region has a width that decreases with increasing depth in the semiconductor layer structure.

In some embodiments, the channel region has a lower first conductivity type doping concentration than the source region and a higher first conductivity type doping concentration than at least a lower portion of the drift region.

In some embodiments, the semiconductor device comprises a silicon carbide-based junction field effect transistor (“JFET”).

Pursuant to aspects of the present disclosure, a semiconductor device is provided that comprises a semiconductor layer structure that comprises a drift region having a first conductivity type and a gate junction region having a second conductivity type, and a gate trench in the semiconductor layer structure. A width of a portion of the gate junction region that extends along a sidewall of the gate trench monotonically changes with increasing depth in the semiconductor layer structure.

In some embodiments, the width of the portion of the gate junction region increases with increasing depth in the semiconductor layer structure.

In some embodiments, the width of the portion of the gate junction region decreases with increasing depth in the semiconductor layer structure.

In some embodiments, at least a portion of the gate junction region comprises sidewalls that angle inwardly with increasing depth in the semiconductor layer structure.

In some embodiments, the gate junction region is on the sidewall of the gate trench and extends underneath the gate trench.

In some embodiments, the semiconductor layer structure further comprises a gate contact region underneath the gate trench and having the second conductivity type.

In some embodiments, the gate contact region has a higher second conductivity type doping concentration than the gate junction region.

In some embodiments, the gate junction region is on sidewalls of the gate contact region and extends underneath the gate contact region.

In some embodiments, the semiconductor device further comprises a gate electrode in the gate trench and in contact with the gate contact region.

In some embodiments, the semiconductor layer structure further comprises a channel region having the first conductivity type on the drift region and a source region having the first conductivity type on the channel region.

In some embodiments, the source region and the channel region are on the sidewall of the gate trench.

In some embodiments, the channel region is on a sidewall of the gate junction region.

In some embodiments, the channel region extends underneath the gate junction region.

In some embodiments, the gate junction region is a first gate junction region, the semiconductor layer structure further comprises a second gate junction region adjacent the first gate junction region, and at least a portion of the channel region between the first gate junction region and the second gate junction region has a width that increases with increasing depth in the semiconductor layer structure.

In some embodiments, the semiconductor layer structure comprises an active region comprising the gate junction region and a termination region comprising at least one termination structure, and the gate junction region and the at least one termination structure have a same doping concentration.

In some embodiments, an upper surface of the semiconductor layer structure in the active region is substantially coplanar with an upper surface of the at least one termination structure.

In some embodiments, the semiconductor device comprises a silicon carbide-based junction field effect transistor (“JFET”).

Pursuant to aspects of the present disclosure, a junction field effect transistor (“JFET”) is provided that comprises a drift region having a first conductivity type, a channel region on the drift region and having the first conductivity type, a source region on the channel region and having the first conductivity type, and a gate junction region comprising a sidewall that contacts the source region, the gate junction region having a second conductivity type.

In some embodiments, at least a portion of the gate junction region has a width that monotonically changes with increasing depth in the semiconductor layer structure.

In some embodiments, the width of the portion of the gate junction region increases with increasing depth in the semiconductor layer structure.

In some embodiments, the width of the portion of the gate junction region decreases with increasing depth in the semiconductor layer structure.

In some embodiments, the channel region extends underneath the gate junction region.

In some embodiments, the drift region contacts the sidewall of the gate junction region.

In some embodiments, the JFET further comprises a gate electrode on an upper surface of the semiconductor layer structure and on the gate junction region.

In some embodiments, an upper surface of the gate junction region is substantially coplanar with an upper surface of the source region.

In some embodiments, the JFET further comprises a gate trench in the semiconductor layer structure and on the gate junction region.

In some embodiments, the gate trench extends in a longitudinal direction in the semiconductor layer structure, and the gate junction region extends underneath the gate trench in the longitudinal direction.

In some embodiments, the source region is on a sidewall of the gate trench, and the channel region is not on the sidewall of the gate trench.

In some embodiments, the JFET further comprises a gate electrode in the gate trench and on the gate junction region.

Pursuant to aspects of the present disclosure, a method of fabricating a semiconductor device is provided that comprises providing a semiconductor layer structure that comprises a drift region having a first conductivity type, forming a preliminary gate junction region in the semiconductor layer structure by implanting second conductivity type dopants into the semiconductor layer structure, and forming a gate trench and a gate junction region in the semiconductor layer structure by etching a portion of the preliminary gate junction region.

In some embodiments, after etching the portion of the preliminary gate junction region, an upper surface of the semiconductor layer structure comprises a pair of adjacent mesas, and the gate trench is between the pair of adjacent mesas.

In some embodiments, the gate junction region is on sidewalls of the gate trench.

In some embodiments, the gate junction region extends underneath the gate trench.

In some embodiments, the method further comprises forming a gate contact region in the semiconductor layer structure by implanting second conductivity type dopants into the gate trench.

In some embodiments, forming the gate contact region in the semiconductor layer structure comprises implanting second conductivity type dopants through the gate trench and into a portion of the gate junction region underneath the gate trench.

In some embodiments, the gate contact region has a higher second conductivity type doping concentration than the gate junction region.

In some embodiments, the gate junction region is on sidewalls of the gate contact region.

In some embodiments, the gate junction region extends underneath the gate contact region.

In some embodiments, the method further comprises forming a spacer in the gate trench.

In some embodiments, the method further comprises forming a gate electrode in the gate trench. The spacer is between the gate electrode and the semiconductor layer structure.

In some embodiments, forming the preliminary gate junction region comprises performing a channeled ion implantation process.

In some embodiments, forming the preliminary gate junction region comprises performing a random ion implantation process.

In some embodiments, the method further comprises forming at least one termination structure by implanting second conductivity type dopants into a termination region of the semiconductor layer structure while concurrently forming the preliminary gate junction region in the semiconductor layer structure.

In some embodiments, the at least one termination structure and the preliminary gate junction region have a same doping concentration.

In some embodiments, the at least one termination structure is formed in the termination region of the semiconductor layer structure, and the preliminary gate junction region is formed in an active region of the semiconductor layer structure.

In some embodiments, an upper surface of the at least one termination structure is substantially coplanar with an upper surface of the semiconductor layer structure in the active region.

In some embodiments, the semiconductor device comprises a silicon carbide-based junction field effect transistor (“JFET”).

Pursuant to aspects of the present disclosure, a method of fabricating a junction field effect transistor (“JFET”) is provided that comprises providing a semiconductor layer structure that comprises a drift region having a first conductivity type, a channel region on the drift region and having the first conductivity type, and a source region on the channel region and having the first conductivity type, and forming a gate junction region in the semiconductor layer structure by implanting second conductivity type dopants into an upper surface of the semiconductor layer structure. An upper surface of the gate junction region is substantially coplanar with an upper surface of the source region.

In some embodiments, the method further comprises forming a gate electrode on the upper surface of the semiconductor layer structure and on the gate junction region.

In some embodiments, the gate electrode is in contact with the gate junction region.

In some embodiments, forming the gate junction region in the semiconductor layer structure comprises performing a channeled ion implantation process.

In some embodiments, forming the gate junction region in the semiconductor layer structure comprises performing a random ion implantation process.

In some embodiments, the gate junction region extends in a depth direction in the semiconductor layer structure through the source and channel regions into the drift region.

In some embodiments, the gate junction region extends in a depth direction in the semiconductor layer structure through the source region into the channel region and is spaced apart from the drift region.

In some embodiments, the method further comprises forming at least one termination structure by implanting second conductivity type dopants into a termination region of the semiconductor layer structure while concurrently forming the gate junction region in the semiconductor layer structure.

In some embodiments, the at least one termination structure is formed in the termination region of the semiconductor layer structure, and the gate junction region is formed in an active region of the semiconductor layer structure.

In some embodiments, the at least one termination structure and the gate junction region have a same doping concentration.

In some embodiments, an upper surface of the at least one termination structure is substantially coplanar with the upper surface of the semiconductor layer structure.

Pursuant to aspects of the present disclosure, a method of fabricating a junction field effect transistor (“JFET”) is provided that comprises providing a semiconductor layer structure that comprises a drift region having a first conductivity type, a channel region on the drift region and having the first conductivity type, and a source region on the channel region and having the first conductivity type, forming a gate trench in the semiconductor layer structure by etching the semiconductor layer structure, and forming a gate junction region in the semiconductor layer structure by implanting second conductivity type dopants into the gate trench. The source region extends deeper in the semiconductor layer structure than the gate trench.

In some embodiments, the method further comprises forming a gate electrode in the gate trench and on the gate junction region.

In some embodiments, the gate electrode is in contact with the gate junction region.

In some embodiments, the gate trench is spaced apart from the channel region.

In some embodiments, forming the gate junction region in the semiconductor layer structure comprises performing a channeled ion implantation process.

In some embodiments, forming the gate junction region in the semiconductor layer structure comprises performing a random ion implantation process.

In some embodiments, the gate junction region extends in a depth direction in the semiconductor layer structure into the drift region.

In some embodiments, the gate junction region extends in a depth direction in the semiconductor layer structure into the channel region and is spaced apart from the drift region.

In some embodiments, the method further comprises forming at least one termination structure by implanting second conductivity type dopants into a termination region of the semiconductor layer structure while concurrently forming the gate junction region in the semiconductor layer structure.

In some embodiments, the at least one termination structure is formed in the termination region of the semiconductor layer structure, and the gate junction region is formed in an active region of the semiconductor layer structure.

In some embodiments, the at least one termination structure and the gate junction region have a same doping concentration.

In some embodiments, an upper surface of the at least one termination structure is substantially coplanar with an upper surface of the gate junction region.

In some embodiments, an upper surface of the at least one termination structure is substantially coplanar with an upper surface of the source region.

Pursuant to aspects of the present disclosure, a method of fabricating a junction field effect transistor (“JFET”) is provided that comprises providing a semiconductor layer structure that comprises an active region and a termination region, and concurrently forming a preliminary gate junction region in the active region and at least one termination structure in the termination region by implanting second conductivity type dopants into an upper surface of the semiconductor layer structure.

In some embodiments, an upper surface of the at least one termination structure is substantially coplanar with the upper surface of the semiconductor layer structure.

In some embodiments, the method further comprises forming a gate trench and a gate junction region in the semiconductor layer structure by etching a portion of the preliminary gate junction region.

### BRIEF DESCRIPTION OF THE DRAWINGS

FIG. 1 is a circuit diagram of an integrated normally-off JFET switch that includes a high-power JFET and a low-power MOSFET in cascode configuration.

FIG. 2A is a schematic plan view of a power JFET according to embodiments of the present disclosure.

FIGS. 2B and 2C are schematic cross-sectional views taken along lines B-B and C-C of FIG. 2A, respectively, according to embodiments of the present disclosure.

FIG. 3 is a schematic cross-sectional view taken along line B-B of FIG. 2A according to further embodiments of the present disclosure.

FIGS. 4A and 4B are schematic cross-sectional views taken along lines B-B and C-C of FIG. 2A, respectively, according to further embodiments of the present disclosure.

FIG. 4C is a schematic cross-sectional view taken along line B-B of FIG. 2A according to further embodiments of the present disclosure.

FIGS. 5A and 5B are schematic cross-sectional views taken along line B-B of FIG. 2A according to further embodiments of the present disclosure.

FIGS. 6A and 6B are schematic cross-sectional views taken along lines B-B and C-C of FIG. 2A, respectively, according to further embodiments of the present disclosure.

FIG. 6C is a schematic cross-sectional view taken along line B-B of FIG. 2A according to further embodiments of the present disclosure.

FIGS. 7A and 7B are schematic cross-sectional views taken along line B-B of FIG. 2A according to further embodiments of the present disclosure.

FIGS. 8A to 8F are schematic cross-sectional views illustrating a method of fabricating a power JFET according to embodiments of the present disclosure.

FIGS. 9A to 9D are schematic cross-sectional views illustrating a method of fabricating a power JFET according to further embodiments of the present disclosure.

FIGS. 10A to 10C are schematic cross-sectional views illustrating a method of fabricating a power JFET according to further embodiments of the present disclosure.

### DETAILED DESCRIPTION

Power JFETs may be desirable for certain applications because they have high current carrying capability, high reliability, and may be formed using a simpler process than a comparably-rated power MOSFET. Moreover, as discussed above, a power JFET can be converted from a normally-on device to a normally-off device by connecting an inexpensive, low-voltage MOSFET in cascode configuration to the power JFET to provide an integrated normally-off JFET switch.

Power JFETs may have different gate designs. For example, a power JFET may have a trench gate design where the active region of the semiconductor layer structure includes a plurality of mesas and trenches (i.e., gate trenches) that are defined in between adjacent mesas. The plurality of mesas are often referred to as “source mesas”. The trenches typically extend in parallel to each other so that each source mesa has a fin shape, with the longitudinal axes of the source mesas extending in parallel to the longitudinal axes of the trenches. Source regions of the JFET, which are semiconductor regions having the same conductivity type as channel regions and a higher doping concentration, are formed in the upper portion of each fin-shaped mesa, which is why the fins are referred to as source mesas.

A trench gate power JFET may include gate junction regions and gate contact regions that are formed in the semiconductor layer structure of the device. The gate junction region and the gate contact region each have a conductivity type opposite to the conductivity type of the channel region, with the gate contact region having a higher doping concentration than the gate junction region. Gate electrodes may be connected to the gate junction regions through the gate contact regions. The gate electrodes are formed in the respective trenches, and the gate contact regions are formed in the semiconductor layer structure underneath the respective trenches. The gate junction regions are formed on sidewalls of the gate contact regions and may also extend onto the sidewalls of the trenches and/or underneath the gate contact regions. The gate junction regions are disposed adjacent the respective channel regions so that application of a gate bias voltage at the gate terminal controls the electric fields in the channel regions. The trench gate design may allow for better control over the electric fields in the channel regions and may enhance carrier mobility in the channel regions.

In a trench gate power JFET, formation of the trenches, gate junction regions and gate contact regions in the active region may involve a number of processing steps. For example, a mask layer may be formed and then patterned using photolithography to form a mask pattern that is used when the semiconductor layer structure is etched to form the trenches and source mesas. A first ion implantation process may be performed to form the gate contact regions. Additional angled (e.g., tilted and twisted) ion implantation processes may be performed into the trenches to form the gate junction regions, and the mask pattern may be removed afterwards. The angled ion implantation processes, however, can be complicated and often lead to greater variation in the actual locations, shapes, and doping profiles of the gate junction regions. As a result, the reliability and performance of the trench gate power JFET may be reduced.

As discussed above, power semiconductor devices typically include edge termination regions that include one or more termination structures such as, for example, guard rings. In a trench gate power JFET, the guard rings have a conductivity type opposite the conductivity type of the channel regions, and hence the guard rings have the same conductivity type as the gate junction regions and the gate contact regions. The above-described processing steps, however, can make it difficult to form the termination structures using the same processing steps that are used to form the trenches, gate junction regions and gate contact regions. As a result, additional processing steps may need to be introduced to form the termination structures. Most processing steps have associated tolerances, and the more processing steps that are performed, the more these tolerances combine to create a greater degree of uncertainty regarding where certain regions (e.g., the guard rings) are formed in a device, the sizes and doping concentrations of the regions, etc.

While trench gate JFET designs typically allow for greater carrier mobility in the channel regions, the processing steps associated with formation of the trenches, gate junction regions and gate contact regions can lead to additional manufacturing costs and introduce more variations in manufactured devices. Planar gate JFET designs and partial trench (i.e., partial recess) gate JFET designs may require less processing steps, and hence a simpler manufacturing process, which reduces manufacturing costs along with variations in manufactured devices.

Pursuant to embodiments of the present disclosure, trench gate power JFETs and methods of forming the same are provided. Pursuant to further embodiments of the present disclosure, planar gate power JFETs, partial trench gate power JFETs, and methods of forming the same are provided.

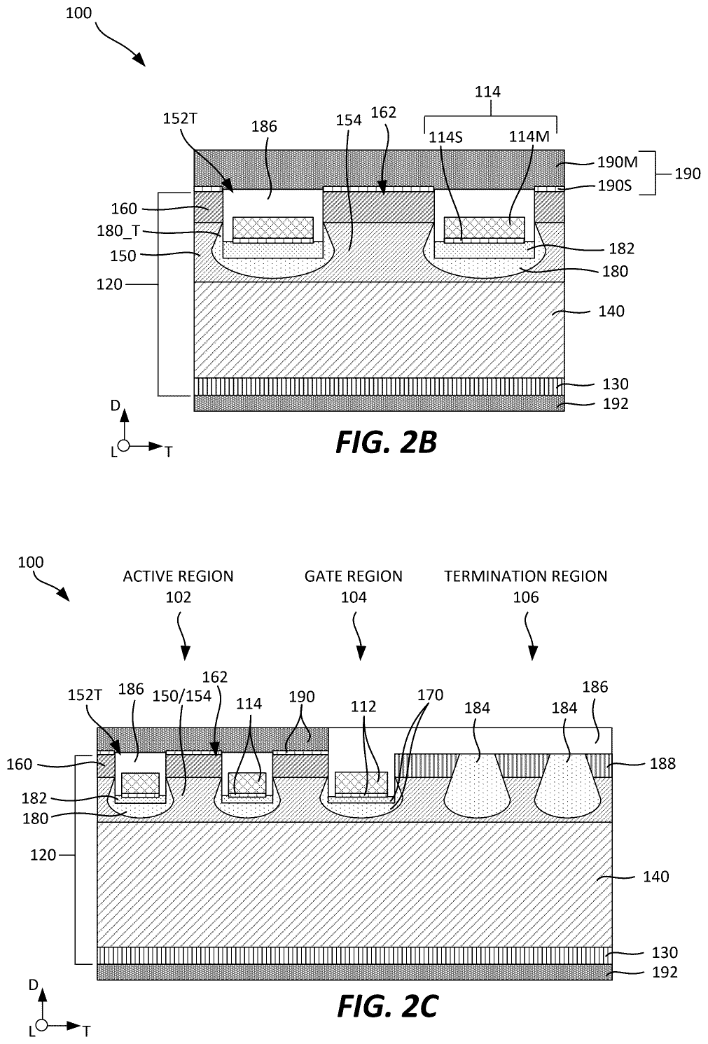

FIG. 2A is a schematic plan view of a power JFET 100 according to embodiments of the present disclosure. In FIG. 2A, several of the upper layers of the JFET 100 including the source and gate bond pads, the source contact, the gate insulating patterns and the upper passivation/protection patterns are omitted to better show the underlying regions of the power JFET 100. FIGS. 2B and 2C are schematic cross-sectional views taken along lines B-B and C-C of FIG. 2A, respectively. To provide additional context, the source contact 190 and the gate insulating patterns 186 that are omitted in FIG. 2A are shown in FIGS. 2B and 2C, although the other layers discussed above are still omitted in FIGS. 2B and 2C.

Referring to FIG. 2A, the power JFET 100 includes an active region 102, a gate region 104, and a termination region 106 that surrounds the active region 102 when the JFET 100 is viewed in plan view (i.e., when viewed from above).

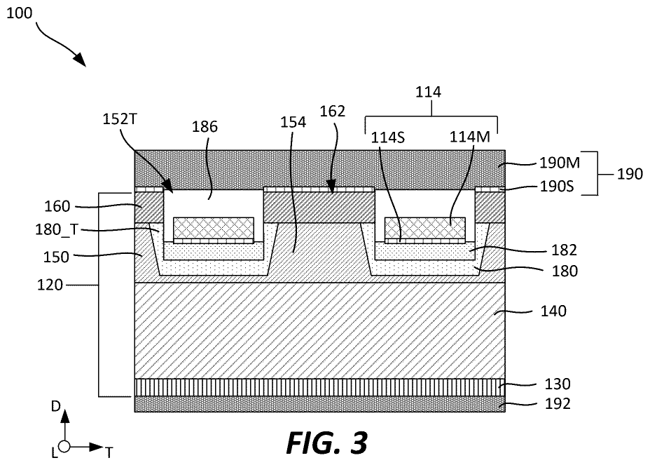

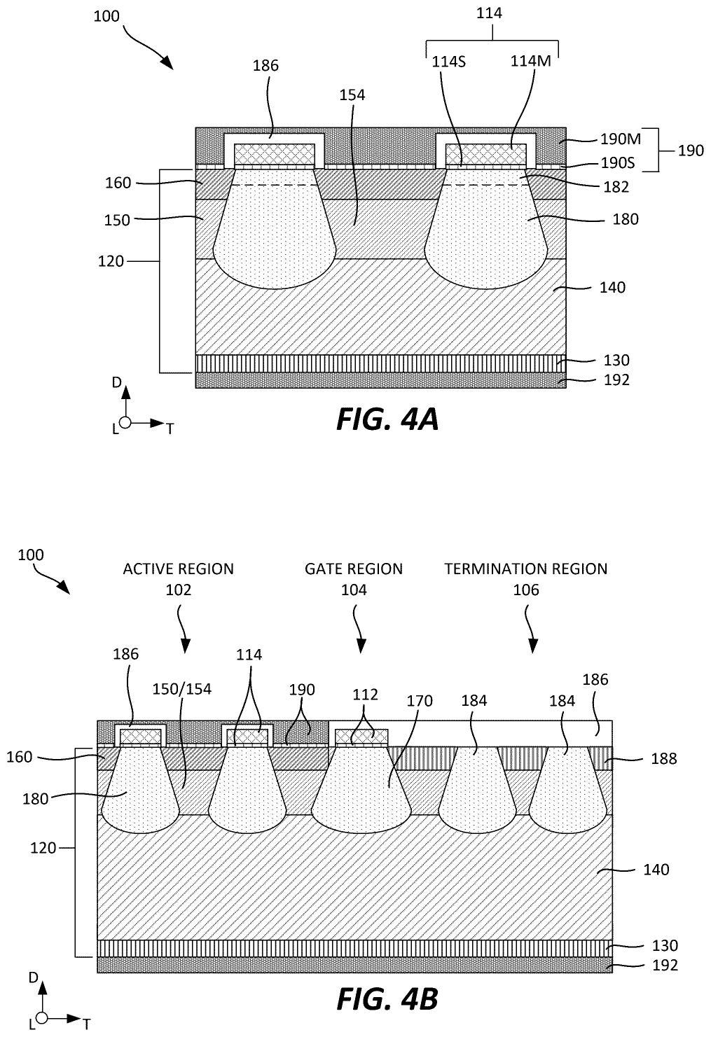

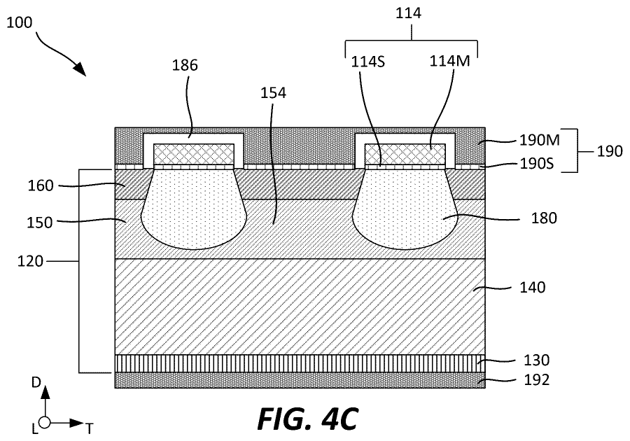

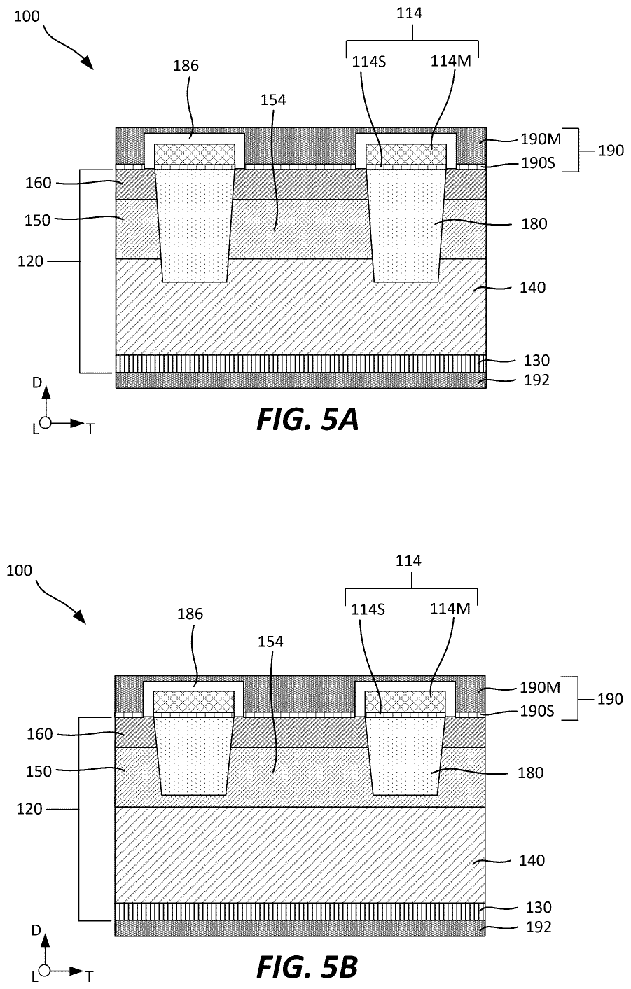

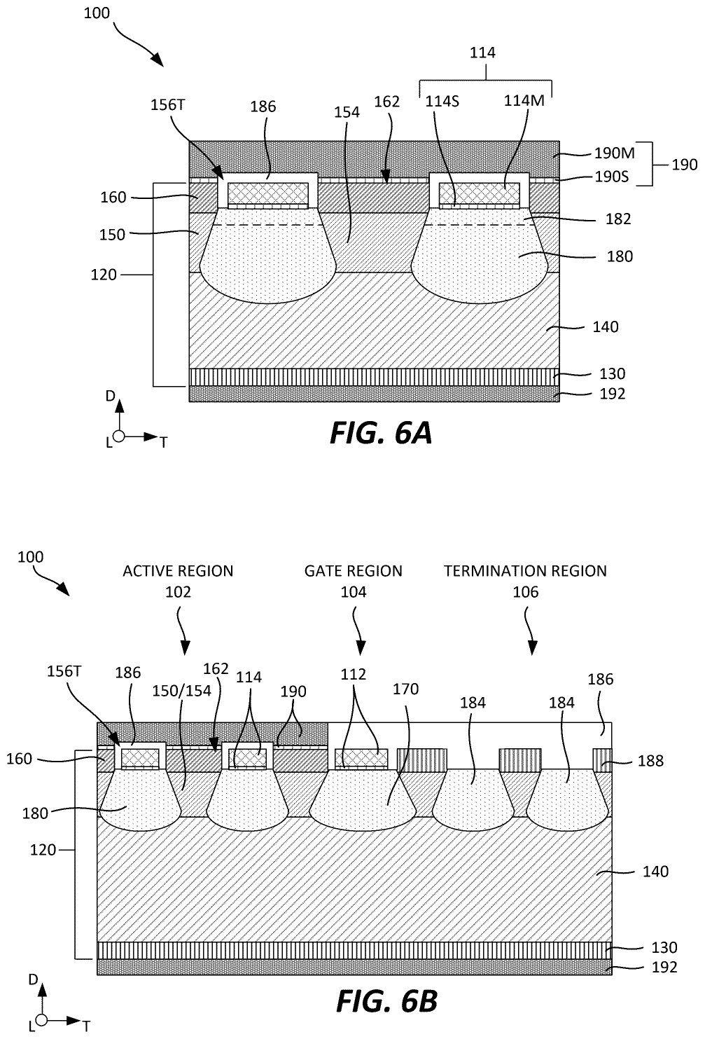

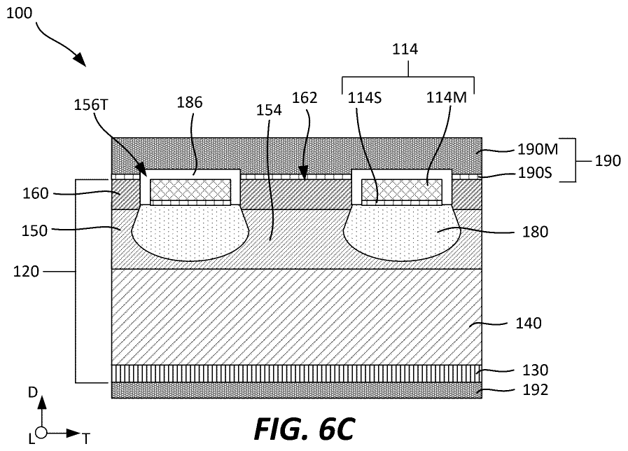

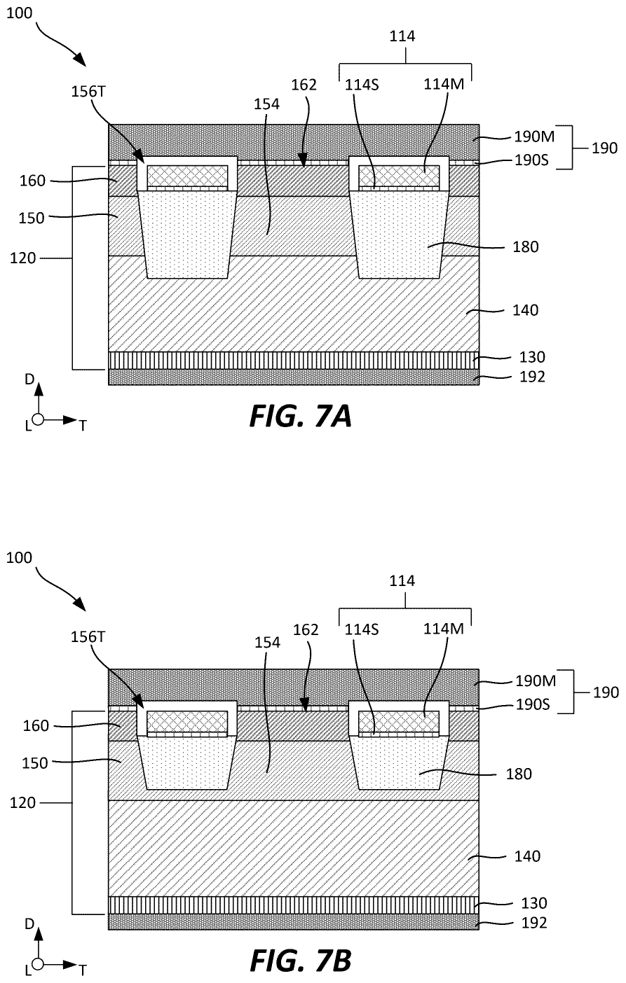

As discussed above, the active region 102 is the portion of the power JFET 100 that acts as a main junction for blocking voltage during off-state operation and current flows through the active region 102 during on-state operation. The power JFET 100 may have a unit cell structure such that a large number of individual “unit cell” JFETs are formed in the active region 102 and are electrically connected in parallel to each other so that the unit cells together function as a single power JFET 100. Each unit cell includes a gate electrode 114. In FIG. 2A, each gate electrode 114 has a longitudinal axis that extends in a longitudinal direction L, and the gate electrodes 114 are spaced apart from each other in a transverse direction T. A depth direction D is also shown in FIG. 2A. In some embodiments, each gate electrode 114 may be formed within a respective gate trench 152T that is formed in an upper surface of a semiconductor layer structure 120 and extends in the longitudinal direction L (see FIGS. 2B-3). In other embodiments, each gate electrode 114 may be formed on the upper surface of the semiconductor layer structure 120 (see FIGS. 4A-5B) or within a respective partial gate trench 156T that is formed in the upper surface of the semiconductor layer structure 120 (see FIGS. 6A-7B).

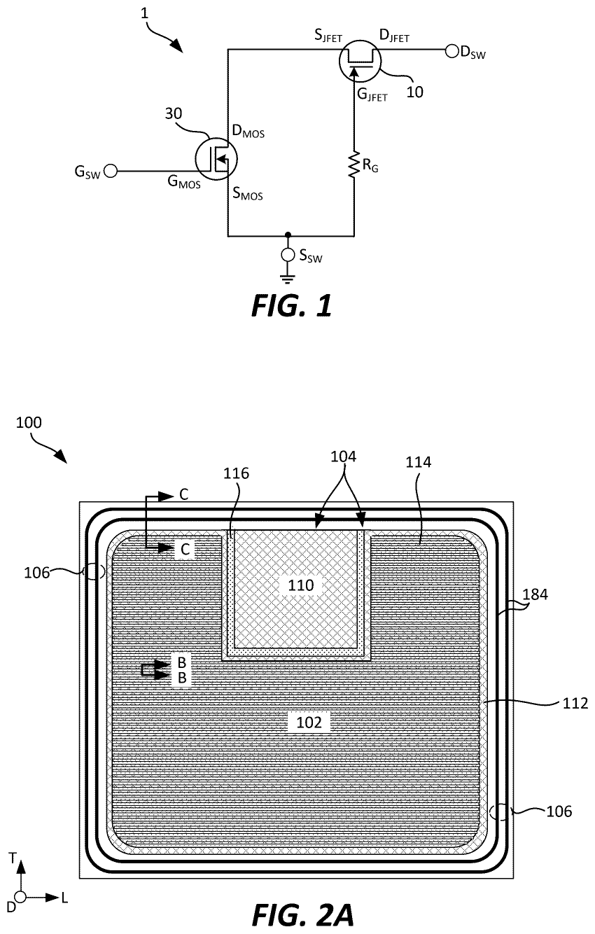

The gate region 104 is the region corresponding to a gate pad 110, a gate bus 112 and any gate resistor 116. The gate pad 110 may include a metal pad and may be provided underneath a metal gate bond pad (not shown) if a separate metal gate bond pad is provided. The gate bond pad (or the gate pad 110 if no separate gate bond pad is provided) may be connected to an external circuit (e.g., to a MOSFET of an integrated normally-off JFET switch) through bond wires, leads or other electrical connections. In some embodiments, the gate pad 110 and the gate bus 112 may each include a metal portion and a metal silicide portion. The gate pad 110 may be physically and electrically connected to the gate bus 112 or may be electrically connected to the gate bus 112 through a gate resistor 116. The gate resistor 116 may include a region (e.g., a p-type region) in the silicon carbide-based semiconductor layer structure 120 of the JFET 100 and is interposed between the gate pad 110 and the gate bus 112 such that gate signals must flow through the gate resistor 116 to pass from the gate pad 110 to the gate bus 112. Since the resistivity of p-type silicon carbide may be many orders of magnitude greater than the resistance of a silicide or metal (e.g., about five orders of magnitude greater than a silicide), the p-type silicon carbide region effectively forms a lumped gate resistor 116. The gate resistor 116 generally corresponds to gate resistor R_{G} in FIG. 1, but is interposed on the electrical path between the gate pad 110 and the gate bus 112 as opposed to being a resistor that is external to the JFET 100. The gate bus 112 may be a high conductivity bus that carries gate signals received from the gate pad 110 to the gate electrodes 114 that are provided in the active region 102. It will be appreciated that the gate resistor 116 may be omitted in some embodiments, and that any appropriate design for the gate bus 112 may be used. For example, in some embodiments, the gate resistor 116 may be omitted and the gate bus 112 may not extend around the gate pad 110 and/or around the bottom of the active region 102. It will also be appreciated that some of the gate electrodes 114 may be directly connected to the gate pad 110 rather than connecting to the gate pad 110 through the gate bus 112 and/or the gate resistor 116.

The termination region 106 is a region that at least partially surrounds the active region 102 and the gate region 104. The termination region 106 is designed to spread the electric fields that extend throughout the semiconductor layer structure 120 during reverse blocking operation out over a greater area in order to reduce electric field crowding effects that may otherwise occur along the outer edges of the active region 102. The termination region 106 may include one or more termination structures 184 such as, for example, guard rings, a junction termination extension (JTE) or the like. In FIG. 2A, the termination structures 184 are schematically shown as being two guard rings 184, which may be p-type regions that are formed as rings around the active region 102 and surround the active region 102 and the gate region 104 when the JFET 100 is viewed in plan view. The number and type of termination structures included in the termination region 106 may be changed from that which is shown in FIG. 2A and is not limited thereto.

FIG. 2B is a schematic cross-sectional view taken along line B-B of FIG. 2A. In particular, FIG. 2B illustrates a portion of the active region 102 of the power JFET 100.

Referring to FIG. 2B, the power JFET 100 includes a plurality of gate electrodes 114 formed in a plurality of gate trenches 152T, respectively, and hence the power JFET 100 may also be referred to as a trench gate power JFET 100. While only two gate trenches 152T are shown in the cross-section of FIG. 2B, it will be appreciated from FIG. 2A that the power JFET 100 may include a large number of gate trenches 152T. The power JFET 100 includes the semiconductor layer structure 120. The semiconductor layer structure 120 may include a substrate 130, a drift region 140, channel regions 150, source regions 160, gate junction regions 180, and gate contact regions 182.

The substrate 130 may be formed of wide bandgap semiconductor materials (e.g., silicon carbide) and may be heavily doped with n-type (n+) dopants in example embodiments. The substrate 130 may have, for example, a doping concentration of 1×10¹⁸ to 1×10²¹ dopants/cm³. In some embodiments, the substrate 130 may be omitted (e.g., removed after epitaxial growth). The substrate 130 may be a thick region (e.g., 50-1000 microns). The longitudinal direction L and the transverse direction T may intersect each other and may be substantially parallel to a lower surface of the substrate 130. In other words, the longitudinal direction L and the transverse direction T may be substantially parallel to a lower surface of the semiconductor layer structure 120. The depth direction D may intersect the longitudinal direction L and the transverse direction T and may be substantially perpendicular to the lower surface of the substrate 130. In other words, the depth direction D may be substantially perpendicular to the lower surface of the semiconductor layer structure 120. As used herein, the longitudinal direction L and the transverse direction T may also be referred to as horizontal directions, and the depth direction D may also be referred to as a vertical direction.

The drift region 140 may be provided on the upper surface of the substrate 130. The drift region 140 may be formed of wide bandgap semiconductor materials (e.g., may be an epitaxially grown silicon carbide layer) and may be a lightly-doped n-type (n−) region. The drift region 140 may have, for example, a doping concentration of 1×10¹⁴ to 1×10¹⁷ dopants/cm³. The drift region 140 may be a thick region, having a vertical height above the substrate 130 of, for example, 3-100 microns (e.g., in the depth direction D). While not specifically shown in FIG. 2B, in some embodiments, an upper portion of the drift region 140 may be more heavily doped (e.g., a doping concentration of 1×10¹⁶ to 2×10¹⁷ dopants/cm³) than the lower portion thereof to provide a current spreading layer in the upper portion of the drift region 140. The thicknesses of the substrate 130 and the drift region 140 are reduced in FIG. 2B as compared to their actual relative sizes (and the same is true in the other cross-sectional views in the present disclosure) in order to better illustrate the thinner regions in the upper portion of the semiconductor layer structure 120.

The channel regions 150 are provided on an upper surface of the drift region 140. For example, each channel region 150 may be defined between a pair of adjacent gate structures. Each gate structure may include a gate trench 152T, a gate electrode 114, a gate contact region 182, and/or a gate junction region 180. The channel region 150 may be formed of wide bandgap semiconductor materials (e.g., epitaxially grown silicon carbide) and may be a moderately doped n-type (n) region. The channel region 150 may have a doping concentration higher than the doping concentration of the lower portion of the drift region 140. For example, a doping concentration of each channel region 150 may be between 1×10¹⁶ to 2×10¹⁷ dopants/cm³.

The channel regions 150 may extend below the gate junction regions 180 and the gate contact regions 182 in the depth direction D, so that the channel regions 150 are all interconnected. In some embodiments, an n-type doping concentration of the channel region 150 may change in the depth direction D. For example, an upper portion of the channel region 150 may have a higher n-type doping concentration than a lower portion of the channel region 150 (e.g., due to the presence of the p-type gate junction region 180 near the lower portion). The lower portion of the channel region 150 may have a higher n-type doping concentration than the lower portion of the drift region 140. Although not shown in FIG. 2B, in other embodiments, the channel regions 150 may extend only as deep as the gate contact regions 182, so that the channel regions 150 are not interconnected.

The source regions 160 are provided on upper surfaces of the channel regions 150. For example, each source region 160 may be defined between a pair of adjacent gate structures respectively including a gate trench 152T, a gate electrode 114, a gate contact region 182, and/or a gate junction region 180. The source regions 160 may be formed of wide bandgap semiconductor materials (e.g., epitaxially grown silicon carbide) and may be heavily-doped n-type (n+) regions. The source regions 160 may have a doping concentration higher than that of the channel regions 150 and may have, for example, a doping concentration of 1×10¹⁸ to 5×10²⁰dopants/cm³.

In some embodiments, the drift region 140, the channel regions 150 and the source regions 160 may all be formed by one or more epitaxial growth processes using the substrate 130 as a seed layer.

A plurality of gate trenches 152T extending in the longitudinal direction L (e.g., into the page in FIG. 2B) are formed in an upper surface of the semiconductor layer structure 120 in the active region 102. The gate trenches 152T may be formed in the semiconductor layer structure 120 with the gate junction regions 180 on sidewalls thereof and may extend downwardly in the depth direction D adjacent the source regions 160 and the channel regions 150. For example, the source regions 160 and the channel regions 150 may be on sidewalls of the gate trenches 152T. Channels 154 may be defined in the channel regions 150 adjacent the gate trenches 152T. The gate trenches 152T may be formed using one or more etching processes. A plurality of upwardly-extending mesas 162 (i.e., extending upwardly from the drift region 140 in the depth direction D) are defined between the gate trenches 152T. Each gate trench 152T may be between a pair of adjacent mesas 162. The source regions 160 are in the upper portions of the mesas 162, so the mesas 162 are sometimes referred to as “source mesas” 162. The channels 154 are formed in the source mesas 162 underneath the source regions 160. A pair of source mesas 162 form the sidewalls of each gate trench 152T.

A plurality of gate contact regions 182 are formed in the bottoms of the gate trenches 152T and hence underneath lower surfaces of the gate trenches 152T. The gate contact regions 182 may extend in the longitudinal direction L underneath the gate trenches 152T. The gate contact regions 182 may be heavily-doped p-type (p+) silicon carbide regions. The gate contact regions 182 may be formed by implanting p-type dopant ions into portions of the semiconductor layer structure 120 that are respectively underneath the gate trenches 152T (i.e., by implanting the p-type dopant ions into the bottom of each gate trench 152T). In some embodiments, the gate contact regions 182 may be formed by implanting p-type dopant ions into portions of the gate junction regions 180 that are respectively underneath the gate trenches 152T. The gate contact regions 182 may have, for example, a doping concentration of 1×10¹⁹ to 5×10²⁰dopants/cm³.

A plurality of gate junction regions 180 are formed in the channel region 150. The gate junction regions 180 may extend downwardly in the depth direction D on sidewalls of the gate trenches 152T and on sidewalls of the gate contact regions 182. The gate junction regions 180 may also extend in the longitudinal direction L on the sidewalls of the gate trenches 152T and on the sidewalls of the gate contact regions 182. In some embodiments, the gate junction regions 180 may extend underneath lower surfaces of the gate trenches 152T and underneath lower surfaces of the gate contact regions 182. The gate junction regions 180 may be formed by ion implantation into the semiconductor layer structure 120 before etching the gate trenches 152T, which streamlines a process for formation of the gate junction regions 180 and reduces variations in the locations, shapes, and doping profiles of the gate junction regions 180. Accordingly, the power JFET 100 may offer improved performance and reliability at lower manufacturing costs.

The gate junction regions 180 may be formed by a random ion implantation process, which will be discussed in greater detail below. The gate junction regions 180 may be moderately-doped p-type (p) regions and may have a doping concentration that is less than the doping concentration of the gate contact regions 182. For example, each gate junction region 180 may have a doping concentration of 5×10¹⁶ to 1×10¹⁹ dopants/cm³.

At least a portion of each gate junction region 180 that is on a sidewall of a respective one of the gate trenches 152T may have a triangular shape 180_T in a cross-sectional view. In other words, at least a portion of each gate junction region 180 that is on a sidewall of a respective one of the gate trenches 152T may have a tapered shape 180_T in a cross-sectional view. The triangular shape 180_T (which may also be referred to as a tapered shape 180_T) may result from a method of forming the gate junction regions 180, which is discussed in greater detail below. As shown in FIG. 2B, a width in the transverse direction T of a portion of the gate junction region 180 that extends along a sidewall of the gate trench 152T may monotonically change such that it increases with increasing depth in the semiconductor layer structure 120 in the depth direction D.

The gate junction region 180 may at least partially surround the gate contact region 182. For example, the gate junction region 180 may be on sidewalls of the gate contact region 182. In some embodiments, the gate junction region 180 may extend underneath a lower surface of the gate contact region 182. As shown in FIG. 2B, a pair of gate junction regions 180 may be adjacent in the transverse direction T, and the channel region 150 may be between the pair of gate junction regions 180. At least a portion of the channel region 150 between the pair of gate junction regions 180 may have a width in the transverse direction T that decreases with increasing depth in the semiconductor layer structure 120 in the depth direction D.

The channel region 150 and the source region 160 may be on a sidewall of the gate trench 152T. In some embodiments, the source region 160 may contact the sidewall of the gate trench 152T. The channel region 150 may be on a sidewall of the gate junction region 180 and may contact the sidewall of the gate junction region 180. The channel region 150 may also be on a sidewall of the gate contact region 182. For example, the gate junction region 180 may be between the gate contact region 182 and the channel region 150.

Random ion implantation techniques may be used to form the gate junction regions 180. This may result in a more uniform distribution of p-type dopant ions for the gate junction regions 180. In addition, a processing step for the gate junction regions 180 may be simpler and may require less equipment setup when random ion implantation techniques are used (e.g., compared to channeled ion implantation techniques), thereby allowing for higher throughput, faster processing times, and reduced manufacturing costs for the power JFET 100.

A plurality of gate electrodes 114 are formed in the gate trenches 152T in the active region 102, respectively. Each gate electrode 114 may include a metal silicide portion 114S and an optional metal portion 114M that is formed on the metal silicide portion 114S. In some embodiments, each gate electrode 114 may only include the metal silicide portion 114S. The metal silicide portion 114S may be formed of metal silicide (e.g., nickel silicide, tungsten silicide, titanium silicide or molybdenum silicide). For example, the metal silicide portion 114S may be formed by depositing a thin metal layer in the gate trench 152T on the semiconductor layer structure 120 and performing an annealing process to diffuse atoms in the metal layer into the semiconductor layer structure 120. The metal portion 114M (if provided) may be formed of metal (e.g., aluminum, tungsten, nickel, titanium, ruthenium and/or an alloy thereof).

Each gate electrode 114 may extend in the longitudinal direction L and may be formed directly on a respective one of the gate contact regions 182 so that upper surfaces of the gate contact regions 182 directly contact the respective metal silicide portions 114S. That is, each gate electrode 114 may be in contact with a respective one of the gate contact regions 182. As discussed above, the gate contact regions 182 may have a higher p-type type doping concentration than the gate junction regions 180. Since the gate contact regions 182 are respectively in contact with the gate electrodes 114, increasing the doping concentrations of the gate contact regions 182 may reduce a contact resistance between the gate electrodes 114 and the gate contact regions 182, which allows for better control of the gate voltage and improves the performance of the power JFET 100.

The gate contact regions 182 electrically connect the gate electrodes 114 to the gate junction regions 180. Each gate contact region 182 may be between a respective one of the gate electrodes 114 and a respective one of the gate junction regions 180. The gate electrodes 114 of the power JFET 100 may be in direct contact with the semiconductor layer structure 120 (e.g., in contact with the gate contact regions 182), unlike insulated gate semiconductor devices where a thin gate insulating layer may separate a gate electrode from a semiconductor layer structure (e.g., MOSFETs, IGBTs, etc.). Each unit cell of the JFET 100 in the active region 102 includes a gate junction region 180, a gate contact region 182 and a gate electrode 114.

The gate electrodes 114 may provide low resistivity paths above each gate contact region 182 so that a gate signal may spread throughout the active region 102 through the gate electrodes 114 and then pass to the gate contact regions 182 along the lengths thereof. The gate signal may then flow from the gate contact regions 182 to the gate junction regions 180.

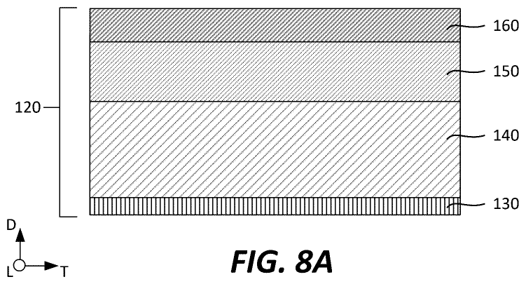

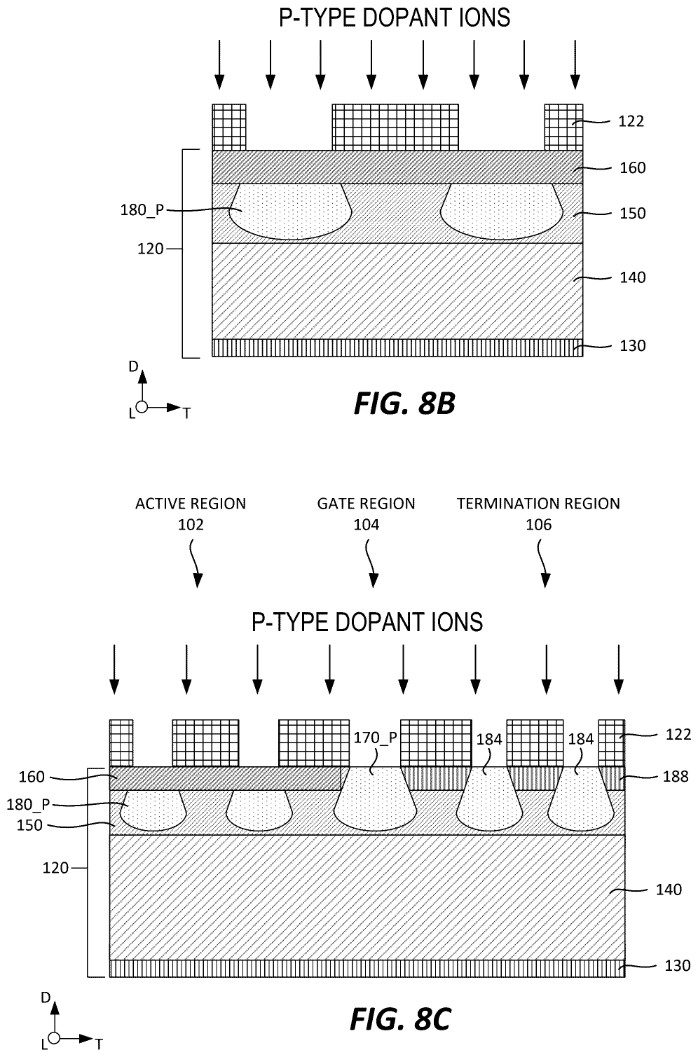

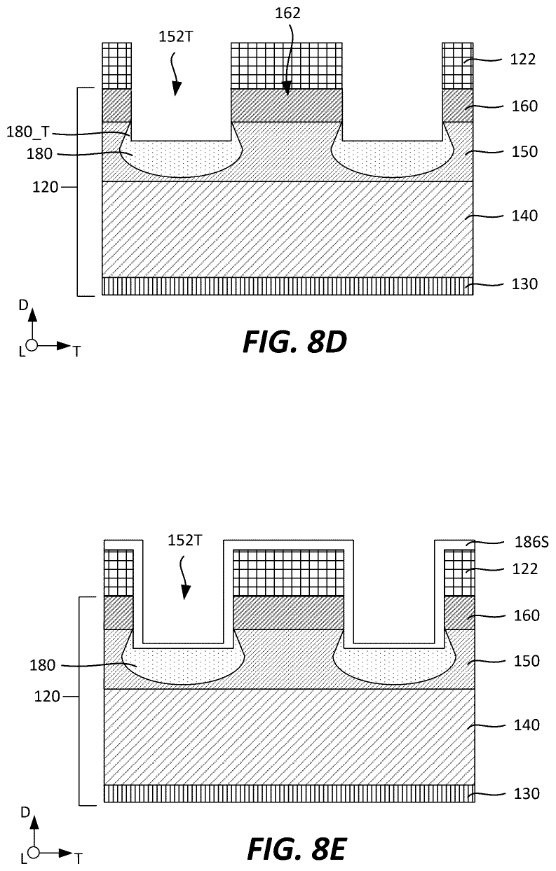

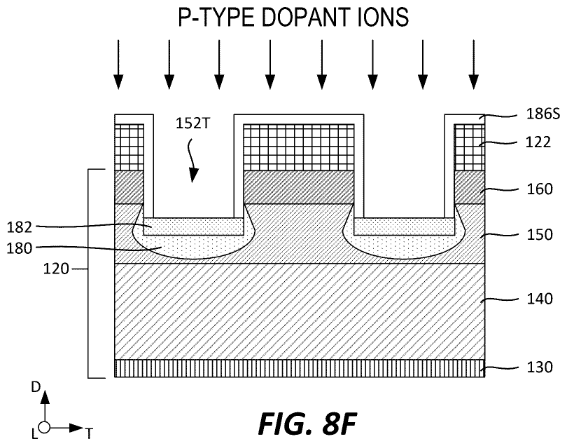

Gate insulating patterns 186 are provided in the gate trenches 152T on upper surfaces and/or side surfaces (i.e., sidewalls) of the gate electrodes 114 (e.g., on the metal portions 114M or on the metal silicide portions 114S if the metal portions 114M are not provided). The gate insulating patterns 186 may include, for example, one or more dielectric materials such as silicon oxide, silicon nitride, silicon oxynitride or the like. As used herein, portions of the gate insulating patterns 186 on sidewalls of the gate electrodes 114 may be referred to as spacers (e.g., see spacer 186S in FIGS. 8E and 8F). Each spacer may be in a respective one of the gate trenches 152T between a sidewall of a respective one of the gate electrodes 114 and the semiconductor layer structure 120. For example, each spacer may be between a gate electrode 114 and a source region 160 (e.g., to prevent a gate-to-source short). In some embodiments, each spacer may also be between a gate electrode 114 and a gate junction region 180. In other embodiments, each spacer may only be provided between a gate electrode 114 and a source region 160.

A source contact 190 is provided on the source regions 160 and the gate insulating patterns 186. The source contact 190 may include one or more layers such as, for example, a diffusion barrier layer, an adhesion layer, and a bulk metal layer. In some embodiments, the source contact 190 may include a metal portion 190M and a metal silicide portion 190S. The gate insulating patterns 186 may insulate the gate electrodes 114 from the source contact 190.

A drain pad 192 (e.g., a metal drain pad) may be provided on the bottom side of the power JFET 100 (e.g., on a lower surface of the substrate 130). The drain pad 192 may be connected to an underlying submount such as a lead frame, a heat sink, a power substrate or the like via soldering, brazing, direct compression or the like. The drain pad 192 may also be referred to as a drain contact.

The substrate 130, the drift region 140, the channel regions 150, and the source regions 160 each have a first conductivity type (e.g., n-type), and the gate junction regions 180 and the gate contact regions 182 each have a second conductivity type (e.g., p-type). Each unit cell of the power JFET 100 may be normally on, meaning that current will flow between the source contact 190 and the drain contact 192 along the channels 154 when no gate signal is applied to the gate electrodes 114 (i.e., when a gate-to-source voltage V_{GS} is zero). When a reverse bias voltage is applied to the gate electrodes 114 (i.e., when the gate-to-source voltage V_{GS} is reverse-biased), depletion regions formed at the p-n junctions between the gate junction regions 180 and the channel regions 150 expand, thereby narrowing widths of the channels 154 included in the channel regions 150. As the gate electrodes 114 are further reverse biased, the depletion regions continue to expand, and the widths of the channels 154 continue to narrow until little to no current can flow between the source contact 190 and the drain contact 192. At this time, the channels 154 are effectively pinched off, and each unit cell of the power JFET 100 may substantially appear as an open circuit. The power JFET 100 may be considered to be in a cut-off mode or a pinch-off mode at this time. For example, in an n-type JFET, a reverse bias voltage may be applied to the gate electrodes 114 when a gate voltage is negative relative to a source voltage (i.e., when the gate-to-source voltage V_{GS} is less than zero), and in a p-type JFET, a reverse bias voltage may be applied to the gate electrodes 114 when the gate voltage is positive relative to the source voltage (i.e., when the gate-to-source voltage V_{GS} is greater than zero).

FIG. 2C is a schematic cross-sectional view taken along line C-C of FIG. 2A. In particular, FIG. 2C illustrates the interface between the edge of the active region 102 and the termination region 106, with the gate region 104 therebetween.

Referring to FIG. 2C, a plurality of termination structures 184 are formed in the termination region 106. As shown in FIG. 2C, the termination structures 184 are a plurality of guard rings 184, but the present disclosure is not limited thereto. In other embodiments, the termination structures 184 may be, for example, a junction termination extension (JTE). Two guard rings 184 are shown in FIG. 2C, but the present disclosure is not limited thereto. In other embodiments, more than two guard rings 184 may be formed in the termination region 106. Each termination structure 184 may include a p-type silicon carbide region that is formed within the n-type channel region 150.

In some embodiments, a p-type region 188 may be formed in the termination region 106. In this case, each termination structure 184 may be formed in the p-type region 188 and the channel region 150. The termination structures 184 and the p-type region 188 form part of the semiconductor layer structure 120 in the termination region 106. The p-type region 188 may be formed of wide bandgap semiconductor materials (e.g., silicon carbide) and may be a lightly-doped p-type (p−) region. The p-type region 188 may have, for example, a doping concentration of 1×10¹⁴ to 1×10¹⁷ dopants/cm³. The p-type region 188 may be formed in an upper portion of the channel region 150 by, for example, ion implantation. In other embodiments, the p-type region 188 may be omitted.

In some embodiments, the termination structures 184 may be formed in the same ion implantation step that is used to form the gate junction regions 180, which streamlines a process for formation of the termination structures 184 and reduces variations in the locations, shapes, and doping profiles of the termination structures 184. The termination structures 184 may have the same doping concentration as the gate junction regions 180. Although not shown in FIG. 2C, in other embodiments, the termination structures 184 may be formed in both the same ion implantation step that is used to form the gate junction regions 180 and the same ion implantation step that is used to form the gate contact regions 182. In this case, each termination structure 184 may include an upper portion that is heavily-doped with p-type dopants and a lower portion that is moderately-doped with p-type dopants. For example, the lower portion may be formed in the same ion implantation step that is used to form the gate junction regions 180 and may thus have the same doping concentration as the gate junction regions 180, and the upper portion may be formed in the same ion implantation step that is used to form the gate contact regions 182 and may thus have the same doping concentration as the gate contact regions 182.

Upper surfaces of the termination structures 184 may be substantially coplanar with an upper surface of the semiconductor layer structure 120 in the active region 102. In other words, upper surfaces of the termination structures 184 may be substantially coplanar with upper surfaces of the mesas 162 (i.e., upper surfaces of the source regions 160).

The termination structures 184 are provided to reduce electric field crowding effects that may otherwise occur at edges of the active region 102. The termination structures 184 that are provided in the termination region 106 may be electrically floating and only capacitively coupled to each other and to the gate on one side and the drain on the other. As shown in FIG. 2C, the source contact 190 is omitted in the termination region 106 and may be replaced with one or more insulating layers 186.

The semiconductor layer structure 120 may further include a gate well region 170. The gate well region 170 is in the gate region 104 and may be formed of wide bandgap semiconductor materials (e.g., silicon carbide). The gate well region 170 may be formed, for example, by implanting p-type dopants into the regions of the semiconductor layer structure 120 on which the gate pad 110 (see FIG. 2A) and the gate bus 112 will be formed in subsequent processes to convert selected portions of the n-type channel region 150 into p-type semiconductor material. The gate well region 170 may be formed to cover a slightly larger area than the area covered by the gate pad 110 and the gate bus 112 when the JFET 100 is viewed in plan view. In some embodiments, the gate well region 170 may be formed in both the same ion implantation step that is used to form the gate junction regions 180 and the same ion implantation step that is used to form the gate contact regions 182. In this case, as shown in FIG. 2C, the gate well region 170 may include a first portion underneath the gate bus 112 that is heavily-doped p-type (p+) and a second portion that is moderately-doped p-type (p) and surrounds the first portion. For example, the first portion may have the same doping concentration as the gate contact regions 182, and the second portion may have the same doping concentration as the gate junction regions 180. In other embodiments, the gate well region 170 may be formed in a separate ion implantation step so that doping concentrations of the gate well region 170, the gate junction regions 180, and the gate contact regions 182 may be set at optimum levels.

The gate region 104 includes the gate bus 112, which may be provided on the semiconductor layer structure 120 in a respective one of the gate trenches 152T. In some embodiments, the gate trench 152T in which the gate bus 112 is formed may be wider than the gate trenches 152T in which the gate electrodes 114 are respectively formed. In some embodiments, the gate bus 112 may include a metal silicide portion and a metal portion on the metal silicide portion. The metal silicide portion may directly contact the gate well region 170 and the metal portion (if provided) may be formed on the metal silicide portion opposite the gate well region 170.

FIG. 3 is a schematic cross-sectional view taken along line B-B of FIG. 2A according to further embodiments of the present disclosure. In particular, FIG. 3 illustrates a portion of the active region 102 of the power JFET 100. For ease of description, differences from the power JFET 100 described above with reference to FIGS. 2A to 2C will mainly be described.

Referring to FIG. 3, the gate junction regions 180 may include sidewalls that angle inwardly with increasing depth in the semiconductor layer structure 120 in the depth direction D. At least a portion of each gate junction region 180 that is on a sidewall of a respective one of the gate trenches 152T may have a tapered shape 180_T in a cross-sectional view.

A width in the transverse direction T of a portion of each gate junction region 180 that extends along a sidewall of a respective one of the gate trenches 152T may monotonically change such that it decreases with increasing depth in the semiconductor layer structure 120 in the depth direction D. As shown in FIG. 3, a pair of gate junction regions 180 may be adjacent in the transverse direction T, and the channel region 150 may be between the pair of gate junction regions 180. At least a portion of the channel region 150 between the pair of gate junction regions 180 may have a width in the transverse direction T that increases with increasing depth in the semiconductor layer structure 120 in the depth direction D.

In the embodiment of FIG. 3, the gate junction regions 180 may be formed by a channeled ion implantation process. When random ion implantation techniques are used, the dopant ions may collide with atoms in the crystal lattice as they pass into the semiconductor layer structure 120, which can cause the dopant ions to be redirected so that they move both laterally and vertically through the crystal lattice. This lateral movement (which is sometimes referred to as “straggle”) may result in an implanted region spreading out laterally (i.e., a “blooming” phenomenon), and the amount of lateral spread tends to increase with increasing depth in the semiconductor layer structure 120.

Channeled ion implantation techniques may avoid lateral spread of the gate junction regions 180 (i.e., may avoid “blooming”), and at least portions of the gate junction regions 180 may thus have widths that decrease with increasing depth in the semiconductor layer structure 120. Accordingly, widths of the channels 154 adjacent the gate junction regions 180 may be increased, which lowers the on-state resistance of the power JFET 100 and minimizes power dissipation. In addition, channeled ion implantation techniques may allow for deeper implant depths and higher doping concentrations at precise locations in the semiconductor layer structure 120. Accordingly, the locations, shapes, and doping profiles of the gate junction regions 180 may be more precise by using channeled ion implantation techniques.

FIGS. 4A and 4B are schematic cross-sectional views taken along lines B-B and C-C of FIG. 2A, respectively, according to further embodiments of the present disclosure. FIG. 4C is a schematic cross-sectional view taken along line B-B of FIG. 2A according to further embodiments of the present disclosure. In particular, FIGS. 4A and 4C illustrate a portion of the active region 102 of the power JFET 100. FIG. 4B illustrates the interface between the edge of the active region 102 and the termination region 106, with the gate region 104 therebetween. For case of description, differences from the power JFET 100 described above with reference to FIGS. 2A to 2C will mainly be described.

Referring to FIGS. 4A to 4C, the power JFET 100 includes a plurality of gate electrodes 114 formed on an upper surface of the semiconductor layer structure 120, and hence the power JFET 100 may also be referred to as a planar gate power JFET 100. Unlike that shown in FIGS. 2B, 2C, and 3, the gate electrodes 114 are not formed in respective gate trenches in the semiconductor layer structure 120.

The semiconductor layer structure 120 may include a plurality of gate junction regions 180. The gate junction regions 180 may be formed by implanting p-type dopant ions into portions of the upper surface of the semiconductor layer structure 120. For example, the gate junction regions 180 may be formed by a random ion implantation process. In some embodiments, an upper portion of each gate junction region 180 may be more heavily doped (e.g., a doping concentration of 1×10¹⁹ to 5×10²⁰ dopants/cm³) than the lower portion thereof to provide a gate contact region 182 in the upper portion of each gate junction region 180. The gate contact regions 182 are shown by dashed lines in FIG. 4A. While not specifically shown in FIGS. 4B, 4C, 5A, and 5B, it will be understood that the gate contact regions 182 may also be provided in the upper portions of the gate junction regions 180, respectively, in each of these power JFETS 100. For example, the gate electrodes 114 (e.g., the metal silicide portions 114S of the gate electrodes 114) may be directly on and electrically connected to the gate contact regions 182, respectively, if provided. In other embodiments, the gate contact regions 182 may be omitted.

The gate junction regions 180 may extend in the longitudinal direction L underneath the gate electrodes 114, respectively. In some embodiments, upper surfaces of the gate junction regions 180 may be substantially coplanar with upper surfaces of the source regions 160. At least a portion of each gate junction region 180 may have a width in the transverse direction T that monotonically changes such that it increases with increasing depth in the semiconductor layer structure 120 in the depth direction D. For example, an average width in the transverse direction T of an upper half of each gate junction region 180 may be less than an average width in the transverse direction T of a lower half of each gate junction region 180. Each unit cell of the JFET 100 in the active region 102 includes a gate junction region 180 and a gate electrode 114.

Each gate electrode 114 may extend in the longitudinal direction L and may be formed directly on a respective one of the gate junction regions 180 so that upper surfaces of the gate junction regions 180 directly contact the respective metal silicide portions 114S. That is, each gate electrode 114 may be electrically connected to a respective one of the gate junction regions 180. When a reverse bias voltage is applied to the gate electrodes 114 (i.e., when the gate-to-source voltage V_{GS} is reverse-biased), depletion regions formed at the p-n junctions between the gate junction regions 180 and the channel regions 150 expand, thereby narrowing widths of the channels 154 included in the channel regions 150. As the gate electrodes 114 are further reverse biased, the depletion regions continue to expand, and the widths of the channels 154 continue to narrow until little to no current can flow between the source contact 190 and the drain contact 192. At this time, the channels 154 are effectively pinched off, and each unit cell of the power JFET 100 may substantially appear as an open circuit.

Planar gate JFETs may require less processing steps, and hence a simpler manufacturing process than trench gate JFETs, which reduces manufacturing costs and variations in manufactured devices. For example, a trench etching process may be omitted when manufacturing planar gate JFETs. Due to their structure and case of manufacturing, planar gate JFETs may be more cost-effective and allow for a higher throughput compared to trench gate JFETs.

Referring to FIGS. 4A and 4B, the gate junction regions 180 may extend adjacent the source region 160, the channel region 150, and the drift region 140. The gate junction regions 180 may extend in the depth direction D through the source region 160 and the channel region 150 into the drift region 140. That is, the gate junction regions 180 may extend from an upper surface of the semiconductor layer structure 120 into the drift region 140. When the gate junction regions 180 extend deeper in the semiconductor layer structure 120 into the drift region 140, the conductivity of the channel regions 150 and the channels 154 included therein may be easier to control, which can enhance the carrier mobility in the channel regions 150.

As shown in FIG. 4A, a pair of gate junction regions 180 may be adjacent in the transverse direction T, with the source region 160, the channel region 150, and a portion of the drift region 140 therebetween. At least a portion of the channel region 150 between the pair of gate junction regions 180 may have a width in the transverse direction T that decreases with increasing depth in the semiconductor layer structure 120 in the depth direction D. The source region 160, the channel region 150, and the drift region 140 may be on a sidewall of the gate junction region 180. For example, the source region 160, the channel region 150, and the drift region 140 may contact the sidewall of the gate junction region 180. A lower surface of the gate junction region 180 may contact the drift region 140.

As shown in FIG. 4B, the termination structures 184 may extend in the depth direction D through the p-type region 188 and the channel region 150 into the drift region 140. The termination structures 184 may be formed in the same ion implantation step that is used to form the gate junction regions 180, and hence may have a same doping concentration as the gate junction regions 180. Upper surfaces of the termination structures 184 may be substantially coplanar with an upper surface of the semiconductor layer structure 120 in the active region 102. In other words, upper surfaces of the termination structures 184 may be substantially coplanar with upper surfaces of the gate junction regions 180 and upper surfaces of the source regions 160.

The gate bus 112 may be formed on an upper surface of the semiconductor layer structure 120 on the gate well region 170. The gate well region 170 may extend in the depth direction D through the channel region 150 into the drift region 140. In some embodiments, the gate well region 170 may be formed in the same ion implantation step that is used to form the gate junction regions 180. In other embodiments, the gate well region 170 may be formed in a separate ion implantation step so that doping concentrations of the gate well region 170 and the gate junction regions 180 may be set at optimum levels.

Referring to FIG. 4C, in further embodiments, the gate junction regions 180 may be substantially the same as the gate junction regions 180 described above with reference to FIGS. 4A and 4B except that the gate junction regions 180 do not extend into the drift region 140. The gate junction regions 180 may extend adjacent the source region 160 and the channel region 150. The channel regions 150 may extend underneath lower surfaces of the gate junction regions 180, so that the channel regions 150 are all interconnected. When the gate junction regions 180 extend shallower in the semiconductor layer structure 120 into the channel region 150, the gate junction regions 180 may be easier to control with respect to depth and doping profile during the ion implantation process, which leads to less variations in manufactured devices and improves the reliability of the power JFET 100.

The gate junction regions 180 may extend through the source region 160 into the channel region 150. That is, the gate junction regions 180 may extend from an upper surface of the semiconductor layer structure 120 into the channel region 150. As shown in FIG. 4C, a pair of gate junction regions 180 may be adjacent in the transverse direction T, with the source region 160 and a portion of the channel region 150 therebetween. At least a portion of the channel region 150 between the pair of gate junction regions 180 may have a width in the transverse direction T that decreases with increasing depth in the semiconductor layer structure 120 in the depth direction D. The source region 160 and the channel region 150 may be on a sidewall of the gate junction region 180. For example, the source region 160 and the channel region 150 may contact the sidewall of the gate junction region 180. A lower surface of the gate junction region 180 may contact the channel region 150.

FIGS. 5A and 5B are schematic cross-sectional views taken along line B-B of FIG. 2A according to further embodiments of the present disclosure. In particular, FIGS. 5A and 5B illustrate a portion of the active region 102 of the power JFET 100. For ease of description, differences from the power JFET 100 described above with reference to FIGS. 4A to 4C will mainly be described.

Referring to FIG. 5A, the gate junction regions 180 may be substantially the same as the gate junction regions 180 described above with reference to FIGS. 4A and 4B except that the gate junction regions 180 include sidewalls that angle inwardly with increasing depth in the semiconductor layer structure 120 in the depth direction D. Accordingly, widths of the channels 154 adjacent the gate junction regions 180 may be increased, which lowers the on-state resistance of the power JFET 100 and minimizes power dissipation. For example, in the embodiment of FIG. 5A, the gate junction regions 180 may be formed by a channeled ion implantation process. The locations, shapes, and doping profiles of the gate junction regions 180 may be more precise by using channeled ion implantation techniques.

As shown in FIG. 5A, a pair of gate junction regions 180 may be adjacent in the transverse direction T, with the source region 160, the channel region 150, and a portion of the drift region 140 therebetween. At least a portion of the channel region 150 between the pair of gate junction regions 180 may have a width in the transverse direction T that increases with increasing depth in the semiconductor layer structure 120 in the depth direction D. At least a portion of each gate junction region 180 may have a width in the transverse direction T that monotonically changes such that it decreases with increasing depth in the semiconductor layer structure 120 in the depth direction D. For example, an average width in the transverse direction T of an upper half of each gate junction region 180 may be greater than an average width in the transverse direction T of a lower half of each gate junction region 180.

Referring to FIG. 5B, the gate junction regions 180 may be substantially the same as the gate junction regions 180 described above with reference to FIG. 4C except that the gate junction regions 180 include sidewalls that angle inwardly with increasing depth in the semiconductor layer structure 120 in the depth direction D. Accordingly, widths of the channels 154 adjacent the gate junction regions 180 may be increased, which lowers the on-state resistance of the power JFET 100 and minimizes power dissipation. For example, in the embodiment of FIG. 5B, the gate junction regions 180 may be formed by a channeled ion implantation process. The locations, shapes, and doping profiles of the gate junction regions 180 may be more precise by using channeled ion implantation techniques.

As shown in FIG. 5B, a pair of gate junction regions 180 may be adjacent in the transverse direction T, with the source region 160 and a portion of the channel region 150 therebetween. At least a portion of the channel region 150 between the pair of gate junction regions 180 may have a width in the transverse direction T that increases with increasing depth in the semiconductor layer structure 120 in the depth direction D. At least a portion of each gate junction region 180 may have a width in the transverse direction T that monotonically changes such that it decreases with increasing depth in the semiconductor layer structure 120 in the depth direction D. For example, an average width in the transverse direction T of an upper half of each gate junction region 180 may be greater than an average width in the transverse direction T of a lower half of each gate junction region 180.

FIGS. 6A and 6B are schematic cross-sectional views taken along lines B-B and C-C of FIG. 2A, respectively, according to further embodiments of the present disclosure. FIG. 6C is a schematic cross-sectional view taken along line B-B of FIG. 2A according to further embodiments of the present disclosure. In particular, FIGS. 6A and 6C illustrate a portion of the active region 102 of the power JFET 100. FIG. 6B illustrates the interface between the edge of the active region 102 and the termination region 106, with the gate region 104 therebetween. For case of description, differences from the power JFET 100 described above with reference to FIGS. 2A to 2C will mainly be described.

Referring to FIGS. 6A to 6C, the power JFET 100 includes a plurality of gate electrodes 114 formed in a plurality of gate trenches 156T, respectively. Unlike the gate trenches 152T shown in FIGS. 2B, 2C, and 3, the gate trenches 156T do not extend into the channel region 150 and hence are only considered to be partial trenches (i.e., partial recesses). Accordingly, the power JFET 100 may also be referred to as a partial trench gate power JFET 100. As used herein, the gate trenches 156T may also be referred to as partial gate trenches 156T.

The semiconductor layer structure 120 may include a plurality of gate junction regions 180. The gate junction regions 180 may be formed by implanting p-type dopant ions into portions of the semiconductor layer structure 120 that are respectively underneath the gate trenches 156T (i.e., by implanting the p-type dopant ions into the bottom of each gate trench 156T). The gate junction regions 180 are formed in the bottoms of the gate trenches 156T and hence underneath lower surfaces of the gate trenches 156T. For example, the gate junction regions 180 may be formed by a random ion implantation process. In some embodiments, an upper portion of each gate junction region 180 may be more heavily doped (e.g., a doping concentration of 1×10¹⁹ to 5×10²⁰ dopants/cm³) than the lower portion thereof to provide a gate contact region 182 in the upper portion of each gate junction region 180. The gate contact regions 182 are shown by dashed lines in FIG. 6A. While not specifically shown in FIGS. 6B, 6C, 7A, and 7B, it will be understood that the gate contact regions 182 may also be provided in the upper portions of the gate junction regions 180, respectively, in each of these power JFETS 100. For example, the gate electrodes 114 (e.g., the metal silicide portions 114S of the gate electrodes 114) may be directly on and electrically connected to the gate contact regions 182, respectively, if provided. In other embodiments, the gate contact regions 182 may be omitted.

The gate trenches 156T extend in the longitudinal direction L and are formed in an upper surface of the semiconductor layer structure 120 in the active region 102. The gate trenches 156T may extend downwardly in the depth direction D from the upper surface of the semiconductor layer structure 120 into the source region 160. The gate trenches 156T may be formed using one or more etching processes. The mesas 162 extend upwardly from the drift region 140 in the depth direction D and are defined between the gate trenches 156T. Each gate trench 156T may be between a pair of adjacent mesas 162. A pair of mesas 162 form the sidewalls of each gate trench 156T.

The source regions 160 may be on sidewalls of the gate trenches 156T, but the channel regions 150 may not be on the sidewalls of the gate trenches 156T. In other words, the source regions 160 may overlap the gate trenches 156T in the transverse direction T, but the channel regions 150 may be free of overlap with the gate trenches 156T in the transverse direction T. As used herein, “an element A overlaps an element B in a direction X” (or similar language) means that there is at least one straight line that extends in the direction X and intersects both the elements A and B. The channel regions 150 may be spaced apart from the gate trenches 156T. The source regions 160 may contact the sidewalls of the gate trenches 156T.

The gate junction regions 180 may extend in the longitudinal direction L underneath the gate electrodes 114, respectively. At least a portion of each gate junction region 180 may have a width in the transverse direction T that monotonically changes such that it increases with increasing depth in the semiconductor layer structure 120 in the depth direction D. For example, an average width in the transverse direction T of an upper half of each gate junction region 180 may be less than an average width in the transverse direction T of a lower half of each gate junction region 180. Each unit cell of the JFET 100 in the active region 102 includes a gate junction region 180 and a gate electrode 114.

Each gate electrode 114 may extend in the longitudinal direction L and may be formed in a respective one of the gate trenches 156T directly on a respective one of the gate junction regions 180 so that upper surfaces of the gate junction regions 180 directly contact the respective metal silicide portions 114S. That is, each gate electrode 114 may be electrically connected to a respective one of the gate junction regions 180. When a reverse bias voltage is applied to the gate electrodes 114 (i.e., when the gate-to-source voltage V_{GS} is reverse-biased), depletion regions formed at the p-n junctions between the gate junction regions 180 and the channel regions 150 expand, thereby narrowing the widths of the channels 154 included in the channel regions 150. As the gate electrodes 114 are further reverse biased, the depletion regions continue to expand, and the widths of the channels 154 continue to narrow until little to no current can flow between the source contact 190 and the drain contact 192. At this time, the channels 154 are effectively pinched off, and each unit cell of the power JFET 100 may substantially appear as an open circuit.

Partial trench gate JFETs may have a simpler manufacturing process than trench gate JFETs, which reduces manufacturing costs along with variations in manufactured devices. For example, a trench etching process may be simplified when manufacturing partial trench gate JFETs since the trenches do not extend as deep into the semiconductor layer structure 120. In addition, partial trench gate JFETs may allow for better carrier mobility in the channel regions 150 as compared to planar gate JFETS. Due to their structure and case of manufacturing, partial trench gate JFETs may be more cost-effective and allow for a higher throughput than trench gate JFETs, while providing better carrier mobility in the channel regions 150 than planar gate JFETs.

Referring to FIGS. 6A and 6B, the gate junction regions 180 may extend adjacent the source region 160, the channel region 150, and the drift region 140. The gate junction regions 180 may extend in the depth direction D through the source region 160 and the channel region 150 into the drift region 140. That is, the gate junction regions 180 may extend from lower surfaces of the gate trenches 156T into the drift region 140. When the gate junction regions 180 extend deeper in the semiconductor layer structure 120 into the drift region 140, the conductivity of the channel regions 150 and the channels 154 included therein may be easier to control, which can enhance the carrier mobility in the channel regions 150.

As shown in FIG. 6A, a pair of gate junction regions 180 may be adjacent in the transverse direction T, with a portion of the source region 160, the channel region 150, and a portion of the drift region 140 therebetween. At least a portion of the channel region 150 between the pair of gate junction regions 180 may have a width in the transverse direction T that decreases with increasing depth in the semiconductor layer structure 120 in the depth direction D. The source region 160, the channel region 150, and the drift region 140 may be on a sidewall of the gate junction region 180. For example, the source region 160, the channel region 150, and the drift region 140 may contact the sidewall of the gate junction region 180. A lower surface of the gate junction region 180 may be in contact with the drift region 140.

As shown in FIG. 6B, the termination structures 184 may extend in the depth direction D through the channel region 150 into the drift region 140. The p-type region 188 may be on sidewalls (e.g., upper portions of the sidewalls) of the termination structures 184. The termination structures 184 may be formed in the same ion implantation step that is used to form the gate junction regions 180, and hence may have a same doping concentration as the gate junction regions 180. Upper surfaces of the termination structures 184 may be substantially coplanar with upper surfaces of the gate junction regions 180.

The gate bus 112 may be formed in a respective one of the gate trenches 156T on the gate well region 170. The gate well region 170 may extend in the depth direction D through the channel region 150 into the drift region 140. In some embodiments, the gate well region 170 may be formed in the same ion implantation step that is used to form the gate junction regions 180. In other embodiments, the gate well region 170 may be formed in a separate ion implantation step so that doping concentrations of the gate well region 170 and the gate junction regions 180 may be set at optimum levels.

Referring to FIG. 6C, in further embodiments, the gate junction regions 180 may be substantially the same as the gate junction regions 180 described above with reference to FIGS. 6A and 6B except that the gate junction regions 180 do not extend into the drift region 140. The gate junction regions 180 may be extend adjancet the source region 160 and the channel region 150. The channel regions 150 may extend underneath lower surfaces of the gate junction regions 180, so that the channel regions 150 are all interconnected. When the gate junction regions 180 extend shallower in the semiconductor layer structure 120 into the channel region 150, the gate junction regions 180 may be easier to control with respect to depth and doping profile during the ion implantation process, which leads to less variations in manufactured devices and improves the reliability of the power JFET 100.

The gate junction regions 180 may extend through the source region 160 into the channel region 150. That is, the gate junction regions 180 may extend from lower surfaces of the gate trenches 156T into the channel region 150. As shown in FIG. 6C, a pair of gate junction regions 180 may be adjacent in the transverse direction T, with a portion of the source region 160 and a portion of the channel region 150 therebetween. At least a portion of the channel region 150 between the pair of gate junction regions 180 may have a width in the transverse direction T that decreases with increasing depth in the semiconductor layer structure 120 in the depth direction D. The source region 160 and the channel region 150 may be on a sidewall of the gate junction region 180. For example, the source region 160 and the channel region 150 may contact the sidewall of the gate junction region 180. A lower surface of the gate junction region 180 may contact the channel region 150.

FIGS. 7A and 7B are schematic cross-sectional views taken along line B-B of FIG. 2A according to further embodiments of the present disclosure. In particular, FIGS. 7A and 7B illustrate a portion of the active region 102 of the power JFET 100. For case of description, differences from the power JFET 100 described above with reference to FIGS. 6A to 6C will mainly be described.

Referring to FIG. 7A, the gate junction regions 180 may be substantially the same as the gate junction regions 180 described above with reference to FIGS. 6A and 6B except that the gate junction regions 180 include sidewalls that angle inwardly with increasing depth in the semiconductor layer structure 120 in the depth direction D. Accordingly, widths of the channels 154 adjacent the gate junction regions 180 may be increased, which lowers the on-state resistance of the power JFET 100 and minimizes power dissipation. For example, in the embodiment of FIG. 7A, the gate junction regions 180 may be formed by a channeled ion implantation process. The locations, shapes, and doping profiles of the gate junction regions 180 may be more precise by using channeled ion implantation techniques.

As shown in FIG. 7A, a pair of gate junction regions 180 may be adjacent in the transverse direction T, with a portion of the source region 160, the channel region 150, and a portion of the drift region 140 therebetween. At least a portion of the channel region 150 between the pair of gate junction regions 180 may have a width in the transverse direction T that increases with increasing depth in the semiconductor layer structure 120 in the depth direction D. At least a portion of each gate junction region 180 may have a width in the transverse direction T that monotonically changes such that it decreases with increasing depth in the semiconductor layer structure 120 in the depth direction D. For example, an average width in the transverse direction T of an upper half of each gate junction region 180 may be greater than an average width in the transverse direction T of a lower half of each gate junction region 180.

Referring to FIG. 7B, the gate junction regions 180 may be substantially the same as the gate junction regions 180 described above with reference to FIG. 6C except that the gate junction regions 180 include sidewalls that angle inwardly with increasing depth in the semiconductor layer structure 120 in the depth direction D. Accordingly, widths of the channels 154 adjacent the gate junction regions 180 may be increased, which lowers the on-state resistance of the power JFET 100 and minimizes power dissipation. For example, in the embodiment of FIG. 7B, the gate junction regions 180 may be formed by a channeled ion implantation process. The locations, shapes, and doping profiles of the gate junction regions 180 may be more precise by using channeled ion implantation techniques.

As shown in FIG. 7B, a pair of gate junction regions 180 may be adjacent in the transverse direction T, with a portion of the source region 160 and a portion of the channel region 150 therebetween. At least a portion of the channel region 150 between the pair of gate junction regions 180 may have a width in the transverse direction T that increases with increasing depth in the semiconductor layer structure 120 in the depth direction D. At least a portion of each gate junction region 180 may have a width in the transverse direction T that monotonically changes such that it decreases with increasing depth in the semiconductor layer structure 120 in the depth direction D. For example, an average width in the transverse direction T of an upper half of each gate junction region 180 may be greater than an average width in the transverse direction T of a lower half of each gate junction region 180.

FIGS. 8A to 8F are schematic cross-sectional views illustrating a method of fabricating a power JFET according to embodiments of the present disclosure.

Referring to FIG. 8A, a semiconductor layer structure 120 may be provided that includes a heavily-doped n-type (n+) substrate 130, a lightly-doped n-type (n−) drift region 140 on the substrate 130, a moderately-doped n-type (n) channel region 150 on the drift region 140, and a heavily-doped n-type (n+) source region 160 on the channel region 150. The substrate 130, the drift region 140, the channel region 150, and the source region 160 may each be formed of wide bandgap semiconductor materials (e.g., silicon carbide).

The drift region 140 may be formed on an upper surface of the substrate 130 by, for example, epitaxial growth. In some embodiments, the n-type dopant concentration may be increased during the growth of an upper portion of the drift region 140 to form a current spreading layer (not shown) in the upper portion of the drift region 140. The channel region 150 may be formed on an upper surface of the drift region 140 by, for example, epitaxial growth. The source region 160 may be formed on an upper surface of the channel region 150 by, for example, epitaxial growth. Although not shown in FIG. 8A, in some embodiments, a lightly-doped p-type (p−) region 188 may be formed in a termination region 106 of the semiconductor layer structure 120 on an upper surface of the channel region 150 (e.g., see FIG. 8C). For example, the p-type region 188 may be formed by an ion implantation process where p-type dopants are selectively implanted into an upper portion of the channel region 150. The drift region 140, the channel region 150, and the source region 160 may all be formed by one or more epitaxial growth processes using the substrate 130 as a seed layer, and each region may be doping during growth and/or via ion implantation to provide their respective doping profiles.

Referring to FIGS. 8B and 8C, a mask layer may be formed on an upper surface of the semiconductor layer structure 120, and the mask layer may be patterned (e.g., using photolithography) to provide a mask pattern 122 that exposes selected portions of the semiconductor layer structure 120 in the active region 102, the gate region 104, and the termination region 106. A plurality of preliminary gate junction regions 180_P may then be formed in the semiconductor layer structure 120 in the active region 102 by implanting p-type dopant ions into the portions of the semiconductor layer structure 120 that are exposed by the mask pattern 122. In some embodiments, termination structures 184 may be concurrently formed in the semiconductor layer structure 120 by implanting the p-type dopant ions into portions of the semiconductor layer structure 120 in the termination region 106 that are exposed by the mask pattern 122. In other words, the preliminary gate junction regions 180_P in the active region 102 and the termination structures 184 in the termination region 106 may be formed in a same ion implantation step by implanting p-type dopant ions into an upper surface of the semiconductor layer structure 120, which streamlines a process for formation of the termination structures 184 and reduces variations in the locations, shapes, and doping profiles of the termination structures 184. The termination structures 184 and the preliminary gate junction regions 180_P may have a same doping concentration.

In some embodiments, a preliminary gate well region 170_P may also be concurrently formed in the semiconductor layer structure 120 by implanting p-type dopant ions into portions of the semiconductor layer structure 120 in the gate region 104 that are exposed by the mask pattern 122. In this case, the preliminary gate well region 170_P and the preliminary gate junction regions 180_P may have a same doping concentration. In other embodiments, a gate well region 170 (e.g., see FIG. 2C) may be formed in a separate ion implantation step so that doping concentrations of the gate well region 170 and the preliminary gate junction regions 180_P may be set at optimum levels.

In some embodiments, a random ion implantation process may be performed to form the preliminary gate junction regions 180_P. For example, the p-type dopant ions may be implanted at an angle of 90° with respect to an upper surface of the semiconductor layer structure 120 (i.e., vertically) during the random ion implantation process. The random ion implantation process may allow for a more uniform distribution of p-type dopant ions in the preliminary gate junction regions 180_P. In addition, the random ion implantation process may be simpler, may require less equipment setup, and may have less manufacturing costs associated therewith (e.g., compared to a channeled ion implantation process). During the random ion implantation process, as the p-type dopant ions pass into the semiconductor layer structure 120, they may collide with atoms in the crystal lattice, which may redirect the p-type dopant ions in lateral directions. This lateral movement may result in the preliminary gate junction regions 180_P spreading out laterally, and the amount of lateral spread may increase with increasing depth in the semiconductor layer structure 120. The preliminary gate junction regions 180_P may thus have widths in the transverse direction T that increase with increasing depth in the semiconductor layer structure 120 in the depth direction D. For example, an average width in the transverse direction T of an upper half of each preliminary gate junction region 180_P may be less than an average width in the transverse direction T of a lower half of each preliminary gate junction region 180_P.

Although not shown in FIG. 8B, in other embodiments, a channeled ion implantation process may be performed to form the preliminary gate junction regions 180_P. As discussed, for example, in U.S. Pat. No. 11,075,264 (“the '264 patent”), the entire content of which is incorporated herein by reference, a channeled ion implantation process refers to an ion implantation process where the dopant ions are implanted along certain crystallographic axes in the semiconductor layer structure 120 where channels are formed, where a channel refers to an area where atoms are not present when viewed along the crystallographic axis. Channeled ion implantation may be performed by angling the ion source with respect to the semiconductor layer structure 120 so that the dopant ions are implanted along a desired crystallographic axis, as explained in further detail in the '264 patent. When dopant ions are implanted along channels in the crystallographic axis, the dopant ions may travel, on average, much farther through the crystal lattice in the semiconductor layer structure 120 before they strike atoms within the crystal lattice than is the case when a random ion implantation process is performed. Consequently, the ions implanted in a channeled ion implantation process may be, on average, implanted to deeper depths while using lower implantation energies. In addition, channeled ion implantation typically results in little to no lateral movement of the implanted region with depth since the dopant ions end up striking fewer atoms and/or are more constrained within the channels. When channeled ion implantation techniques are used, not only may the dopant ions be implanted to deeper depths using less implantation energy, but the reduced scattering may allow the implanted regions to have more vertical or inwardly angled sidewalls than is possible when random ion implantation techniques are used.

In 4H silicon carbide based devices, there are three sets of crystallographic axes which are amenable to channeled ion implantation, namely (1) the <0001> crystallographic axis, (2) the <11-23> crystallographic axis (and the symmetrically equivalent <-1-123>, <1-213>, <-12-13>, <2-1-13> and <-2113> crystallographic axes) and (3) the <11-20> crystallographic axis. In embodiments where a channeled ion implantation process is used to form the preliminary gate junction regions 180_P, the channeled ion implantation process may be performed along any of these crystallographic axes of the semiconductor layer structure 120. When the preliminary gate junction regions 180_P are formed by a channeled ion implantation process, the preliminary gate junction regions 180_P may have inwardly angled sidewalls and may thus have widths in the transverse direction T that decrease with increasing depth in the semiconductor layer structure 120 in the depth direction D. For example, in this case, an average width in the transverse direction T of an upper half of each preliminary gate junction region 180_P may be greater than an average width in the transverse direction T of a lower half of each preliminary gate junction region 180_P.

The preliminary gate junction regions 180_P may be moderately-doped p-type (p) regions and may have a doping concentration of, for example, 5×10¹⁶ to 1×10¹⁹ dopants/cm³. The preliminary gate junction regions 180_P may be formed by ion implantation into the semiconductor layer structure 120 (e.g., into the source region 160 and the channel region 150) before etching gate trenches in the semiconductor layer structure 120. As shown in FIGS. 8B and 8C, the preliminary gate junction regions 180_P may not extend to an upper surface of the semiconductor layer structure 120. For example, the ion implantation process used to form the preliminary gate junction regions 180_P may not change the conductivity type of portions of the source region 160 where p-type dopants are implanted (e.g., due the source region 160 being heavily doped n-type (n+)). Upper surfaces of the preliminary gate junction regions 180_P may thus contact a lower surface of the source region 160.

Referring to FIG. 8D, an etching process may be performed using the mask pattern 122 as an etching mask to form a plurality of gate trenches 152T in the upper surface of the semiconductor layer structure 120 in the active region 102. During the etching process, a plurality of gate junction regions 180 may also be formed in the semiconductor layer structure 120 by etching a portion (e.g., an upper portion) of each preliminary gate junction region 180_P. In other words, the gate trenches 152T and the gate junction regions 180 may be concurrently formed in the semiconductor layer structure 120 by etching a portion of each preliminary gate junction region 180_P. Portions of the source region 160 may also be etched during the etching process to form the gate trenches 152T and the gate junction regions 180. Although not shown in FIG. 8D, a mask pattern may be formed in the termination region 106 to cover the termination structures 184 during the etching process to form the gate trenches 152T and the gate junction regions 180. The preliminary gate well region 170_P (see FIG. 8C) formed in the gate region 104 may be partially etched during the etching process.

For example, the formation of the gate trenches 152T may convert the channel region 150 and the source region 160 into a plurality of channel regions 150 and a plurality of source regions 160, respectively. After etching a portion of each preliminary gate junction region 180_P, an upper surface of the semiconductor layer structure 120 may include a plurality of mesas 162. The source regions 160 are in the upper portions of the mesas 162. Each gate trench 152T may be between a pair of adjacent mesas 162.

In some embodiments, the same mask pattern 122 used to form the preliminary gate junction regions 180_P may be used to form the gate trenches 152T. In other embodiments, the mask pattern 122 may be removed after forming the preliminary gate junction regions 180_P, a new mask layer may be formed on an upper surface of the semiconductor layer structure 120, and the new mask layer may be patterned to provide a mask pattern that exposes selected portions of the semiconductor layer structure 120 where the gate trenches 152T are to be formed.

By forming the preliminary gate junction regions 180_P in the semiconductor layer structure 120 before forming the gate trenches 152T, the gate junction regions 180 and the gate trenches 152T may be concurrently formed in the same processing step by etching portions of the preliminary gate junction regions 180_P. Accordingly, a fabrication method for the power JFET may be simplified, and a number of manufacturing tolerances may also be reduced, which reduces a degree of uncertainty related to where the gate junction regions 180 are formed in the semiconductor layer structure 120, along with the sizes and doping concentrations of the gate junction regions 180. In addition, by forming the preliminary gate junction regions 180_P in the semiconductor layer structure 120 before forming the gate trenches 152T, the gate junction regions 180 may be easily formed on sidewalls and lower surfaces of the gate trenches 152T adjacent the channel regions 150. This also avoids having to perform angled ion implantation processes into the sidewalls and lower surfaces of the gate trenches 152T to form the gate junction regions 180, as the angled ion implantation processes can be complicated and often lead to greater variation in the actual locations, shapes, and doping profiles of the gate junction regions 180.

After the gate trenches 152T are etched in the semiconductor layer structure 120, at least a portion of each gate junction region 180 that is on a sidewall of a respective one of the gate trenches 152T may have a triangular shape 180_T (i.e., a tapered shape 180_T) in a cross-sectional view. A width in the transverse direction T of a portion of each gate junction region 180 that extends along a sidewall of a respective one of the gate trenches 152T may monotonically change such that it increases with increasing depth in the semiconductor layer structure 120 in the depth direction D. Although not shown in FIG. 8D, in embodiments where the preliminary gate junctions regions 180_P are formed by a channeled ion implantation process, the preliminary gate junction regions 180_P may have sidewalls that angle inwardly with increasing depth in the semiconductor layer structure 120, and thus when the gate trenches 152T are etched in the semiconductor layer structure 120, a width in the transverse direction T of a portion of each gate junction region 180 that extends along a sidewall of a respective one of the gate trenches 152T may monotonically change such that it decreases with increasing depth in the semiconductor layer structure 120 in the depth direction D (e.g., see the gate junction regions 180 in FIG. 3).

Referring to FIG. 8E, a spacer 186S may be formed in the gate trenches 152T. The spacer 186S may be deposited on the semiconductor layer structure 120 and etched such that the spacer 186S conformally extends along inner sidewalls and a lower surface of each gate trench 152T. For example, the spacer 186S may be blanket deposited on the semiconductor layer structure 120 and then an etching process may be performed on the spacer 186S. The spacer 186S may be formed using a deposition process (e.g., physical vapor deposition (PVD), chemical vapor deposition (CVD), plasma-enhanced CVD (PECVD), atomic layer deposition (ALD), plasma-enhanced ALD (PEALD), or the like) and then etched. The spacer 186S may be a single layer or may include multiple layers of uniform and/or non-uniform composition. The spacer 186S may include, for example, one or more dielectric materials such as silicon oxide, silicon nitride, silicon oxynitride or the like.

Referring to FIG. 8F, a plurality of gate contact regions 182 may be formed in the semiconductor layer structure 120 by implanting p-type dopant ions into the gate trenches 152T (e.g., into the bottoms of the gate trenches 152T). In some embodiments, the gate contact regions 182 may be formed by implanting p-type dopant ions through the gate trenches 152T and into portions of the gate junction regions 180 underneath the gate trenches 152T. For example, upper portions of the gate junction regions 180 underneath the gate trenches 152T may be converted into the gate contact regions 182. The gate contact regions 182 may be heavily-doped p-type (p+) silicon carbide regions. The gate contact regions 182 may have, for example, a doping concentration of 1×10¹⁹ to 5×10²⁰ dopants/cm³.

In some embodiments, a random ion implantation process may be used to form the gate contact regions 182. During the random ion implantation process, p-type dopant ions may be implanted at high energy into the semiconductor layer structure 120. For example, the p-type dopant ions may be implanted at an angle of 90° with respect to an upper surface of the semiconductor layer structure 120 (i.e., vertically) during the random ion implantation process. The gate contact regions 182 may exhibit significantly less lateral spread than the gate junction regions 180 since the gate contact regions 182 are formed by implanting p-type dopant ions into the gate trenches 152T instead of an upper surface of the semiconductor layer structure 120 and do not extend as deep in the semiconductor layer structure 120 as the gate junction regions 180. In other embodiments, the gate contact regions 182 may be formed by a channeled ion implantation process.

In some embodiments, portions of the spacer 186S on lower surfaces of the gate trenches 152T may be removed before forming the gate contact regions 182 in the semiconductor layer structure 120. In other embodiments, the gate contact regions 182 may be formed in the semiconductor layer structure 120 by implanting p-type dopant ions into the gate trenches 152T and through portions of the spacer 186S on lower surfaces of the gate trenches 152T.

Although not shown in FIG. 8F, the preliminary gate well region 170_P (see FIG. 8C) may be converted to a gate well region 170 (see FIG. 2C) by implanting p-type dopant ions into the semiconductor layer structure 120 in the gate region 104 in the same ion implantation step that is used to form the gate contact regions 182. In some embodiments, upper portions of the termination structures 184 may also be implanted with p-type dopant ions in the same ion implantation step that is used to form the gate contact regions 182. In this case, each termination structure 184 may include an upper portion that is heavily-doped with p-type dopants and a lower portion that is moderately-doped with p-type dopants. For example, the lower portion may be formed in the same ion implantation step that is used to form the preliminary gate junction regions 180_P and may thus have the same doping concentration as the gate junction regions 180, and the upper portion may be formed in the same ion implantation step that is used to form the gate contact regions 182 and may thus have the same doping concentration as the gate contact regions 182.

Referring back to FIGS. 2B and 2C, a plurality of gate electrodes 114 may be formed in the gate trenches 152T, respectively, in the active region 102. Gate insulating patterns 186 may be formed in the gate trenches 152T on the gate electrodes 114 (e.g., on the metal portions 114M or on the metal silicide portions 114S if the metal portions 114M are not provided) to cover each gate electrode 114. A source contact 190 may be formed on the source regions 160 and the gate insulating patterns 186. A drain pad 192 (e.g., a metal drain pad) may be formed on the bottom side of the power JFET 100 (e.g., on a lower surface of the substrate 130 opposite the drift region 140). Accordingly, a trench gate power JFET 100 may be formed.

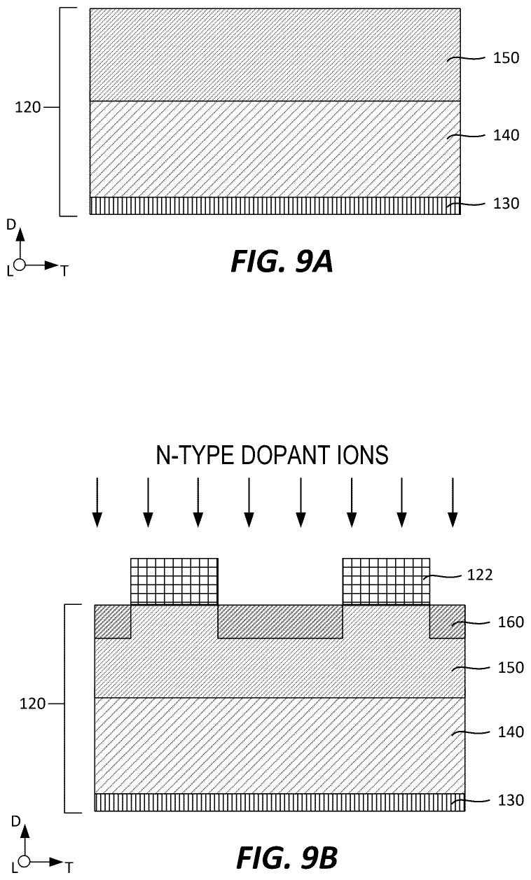

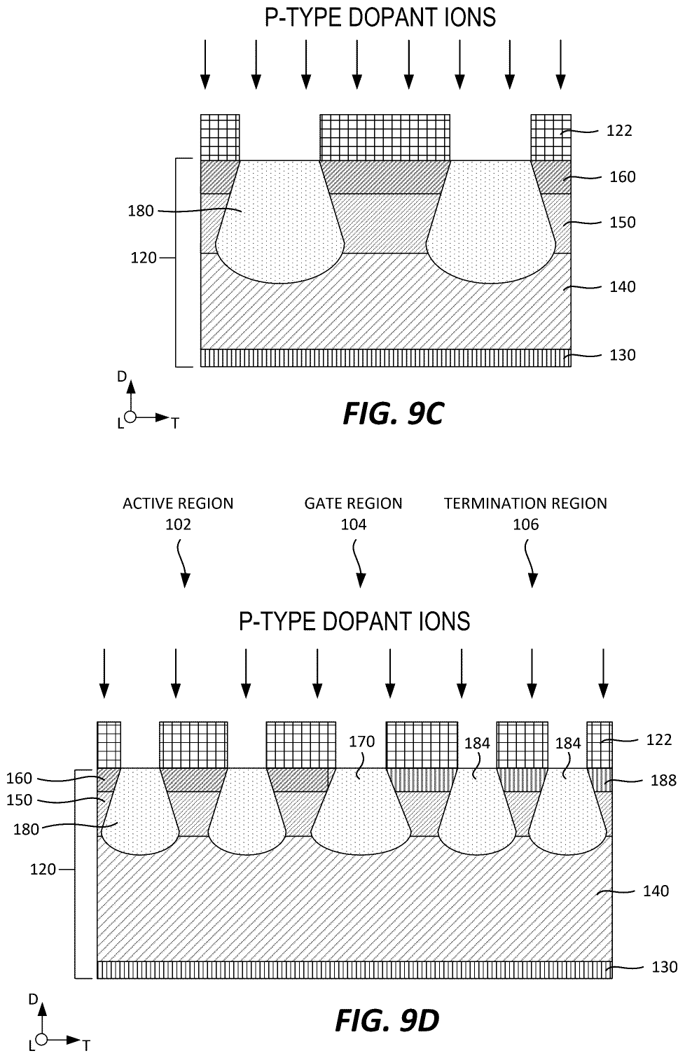

FIGS. 9A to 9D are schematic cross-sectional views illustrating a method of fabricating a power JFET according to further embodiments of the present disclosure.

Referring to FIG. 9A, a semiconductor layer structure 120 may be provided that includes a heavily-doped n-type (n+) substrate 130, a lightly-doped n-type (n−) drift region 140 on the substrate 130, and a moderately-doped n-type (n) channel region 150 on the drift region 140. The substrate 130, the drift region 140, and the channel region 150 may be provided in the same manner as discussed above with respect to FIG. 8A.

Referring to FIG. 9B, a mask layer may be formed on an upper surface of the semiconductor layer structure 120, and the mask layer may be patterned to provide a mask pattern 122 that exposes selected portions of the semiconductor layer structure 120 in the active region 102. Source regions 160 may then be formed in the semiconductor layer structure 120 by implanting n-type dopant ions into portions of the upper surface of the semiconductor layer structure 120 that are exposed by the mask pattern 122. For example, upper portions of the channel region 150 may be converted into the source regions 160. The source regions 160 may be heavily-doped n-type (n+) regions and may have, for example, a doping concentration of 1×10¹⁸ to 5×10²⁰ dopants/cm³. Accordingly, a semiconductor layer structure 120 may be provided that includes a substrate 130, a drift region 140 on the substrate 130, a channel region 150 on the drift region 140, and a source region 160 on the channel region 150.

Referring to FIGS. 9C and 9D, the mask pattern 122 shown in FIG. 9B may be removed, a new mask layer may be formed on an upper surface of the semiconductor layer structure 120, and the new mask layer may be patterned to provide a new mask pattern 122 that exposes selected portions of the semiconductor layer structure 120 in the active region 102, the gate region 104, and the termination region 106. For example, in the active region 102, the new mask pattern 122 may cover the source regions 160. A plurality of gate junction regions 180 may then be formed in the semiconductor layer structure 120 by implanting p-type dopant ions into portions of the semiconductor layer structure 120 in the active region 102 that are exposed by the new mask pattern 122. For example, the p-type dopants may be implanted into an upper surface of the semiconductor layer structure 120 and may extend into portions of the channel region 150 that are exposed by the new mask pattern 122. The gate junction regions 180 may be moderately-doped p-type (p) regions and may have a doping concentration of, for example, 5×10¹⁶ to 1×10¹⁹ dopants/cm³. Although not specifically shown in FIGS. 9C and 9D, in some embodiments, an additional ion implantation step may be performed into upper portions of the gate junction regions 180 to form heavily-doped p-type (p+) regions in the upper portions of the gate junction regions 180, respectively, adjacent the source regions 160.

The gate junction regions 180 may extend through the source and channel regions 160 and 150 into the drift region 140. Upper surfaces of the gate junction regions 180 may be substantially coplanar with an upper surface of the semiconductor layer structure 120. For example, upper surfaces of the gate junction regions 180 may be substantially coplanar with upper surfaces of the source regions 160.

In some embodiments, termination structures 184 may be concurrently formed in the semiconductor layer structure 120 by implanting the p-type dopant ions into portions of the semiconductor layer structure 120 in the termination region 106 that are exposed by the new mask pattern 122. In other words, the gate junction regions 180 in the active region 102 and the termination structures 184 in the termination region 106 may be formed in a same ion implantation step by implanting p-type dopant ions into an upper surface of the semiconductor layer structure 120, which streamlines a process for formation of the termination structures 184 and reduces variations in the locations, shapes, and doping profiles of the termination structures 184. The termination structures 184 and the gate junction regions 180 may have a same doping concentration.

In some embodiments, a gate well region 170 may also be concurrently formed in the semiconductor layer structure 120 by implanting p-type dopant ions into portions of the semiconductor layer structure 120 in the gate region 104 that are exposed by the new mask pattern 122. In this case, the gate well region 170 and the gate junction regions 180 may have a same doping concentration. In other embodiments, the gate well region 170 may be formed in a separate ion implantation step so that doping concentrations of the gate well region 170 and the gate junction regions 180 may be set at optimum levels.

The gate junction regions 180 may extend in the depth direction D in the semiconductor layer structure 120 through the source and channel regions 160 and 150 into the drift region 140. Although not shown in FIGS. 9C and 9D, in other embodiments, the p-type dopants ions used to form the gate junction regions 180 may be implanted at lower energies so that the gate junction regions 180 extend through the source region 160 into the channel region 150 but do not reach the drift region 140. In this case, the gate junction regions 180 may extend in the depth direction D in the semiconductor layer structure 120 through the source region 160 into the channel region 150, while being spaced apart from the drift region 140 in the depth direction D (e.g., see the gate junction regions 180 in FIG. 4C).

While not specifically shown in FIGS. 9C and 9D, in some embodiments, the p-type dopant concentration may be increased in an upper portion of each gate junction region 180 to form a gate contact region in the upper portion of each gate junction region 180, and hence an upper portion of each gate junction region 180 may be more heavily doped than the lower portion thereof (e.g., see the gate contact regions 182 in FIG. 4A).

In some embodiments, a random ion implantation process may be performed to form the gate junction regions 180. For example, p-type dopant ions may be implanted at an angle of 90° with respect to an upper surface of the semiconductor layer structure 120 (i.e., vertically) during the random ion implantation process. The random ion implantation process may result in the gate junction regions 180 spreading out laterally, and the amount of lateral spread may increase with increasing depth in the semiconductor layer structure 120. The gate junction regions 180 may thus have widths that monotonically change such that they increase in the transverse direction T with increasing depth in the semiconductor layer structure 120 in the depth direction D. Although not shown in FIGS. 9C and 9D, in other embodiments, a channeled ion implantation process may be performed to form the gate junction regions 180, and the gate junction regions 180 may have sidewalls that angle inwardly with increasing depth in the semiconductor layer structure 120 in the depth direction D. In this case, the gate junction regions 180 may have widths that monotonically change such that they decrease in the transverse direction T with increasing depth in the semiconductor layer structure 120 in the depth direction D (e.g., see the gate junction regions 180 in FIG. 5A).

Referring back to FIGS. 4A and 4B, a plurality of gate electrodes 114 may be formed on an upper surface of the semiconductor layer structure 120 in the active region 102. The plurality of gate electrodes 114 may be in contact with and electrically connected to the gate junction regions 180, respectively. In other embodiments, the gate electrodes 114 may be in contact with gate contact regions 182 (if provided), respectively. Gate insulating patterns 186 may be formed on the gate electrodes 114 (e.g., on the metal portions 114M or on the metal silicide portions 114S if the metal portions 114M are not provided) to cover each gate electrode 114. A source contact 190 may be formed on the source regions 160 and the gate insulating patterns 186. A drain pad 192 (e.g., a metal drain pad) may be formed on the bottom side of the power JFET 100 (e.g., on a lower surface of the substrate 130 opposite the drift region 140). Accordingly, a planar gate power JFET 100 may be formed.

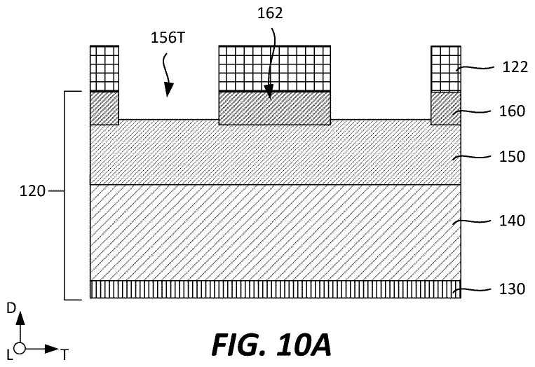

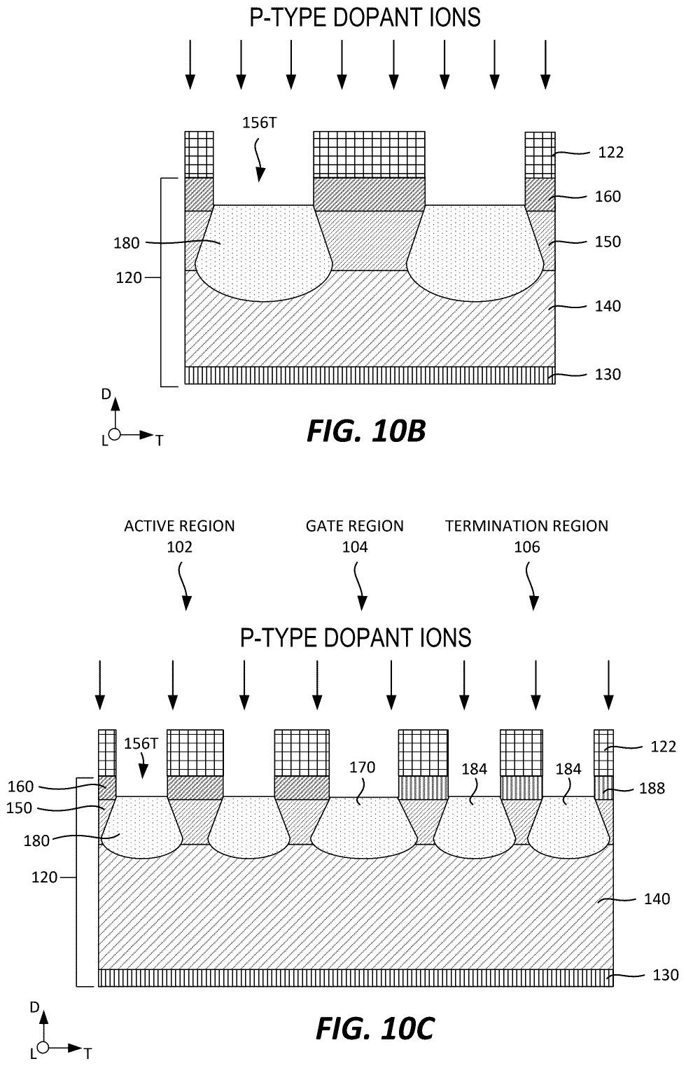

FIGS. 10A to 10C are schematic cross-sectional views illustrating a method of fabricating a power JFET according to further embodiments of the present disclosure.

Referring to FIG. 10A, after the steps described above with reference to FIGS. 9A and 9B, the mask pattern 122 shown in FIG. 9B may be removed, a new mask layer may be formed on an upper surface of the semiconductor layer structure 120, and the new mask layer may be patterned to provide a new mask pattern 122 that exposes selected portions of the semiconductor layer structure 120 in the active region 102. For example, the new mask pattern 122 may cover the source regions 160. An etching process may then be performed using the new mask pattern 122 as an etching mask to form a plurality of gate trenches 156T in the upper surface of the semiconductor layer structure 120 in the active region 102. The gate trenches 156T may be formed in the semiconductor layer structure 120 by etching the semiconductor layer structure 120. For example, the gate trenches 156T may be formed in the semiconductor layer structure 120 by etching upper portions of the channel region 150 exposed by the new mask pattern 122. The source regions 160 may extend deeper in the semiconductor layer structure 120 in the depth direction D than the gate trenches 156T. The source regions 160 may be on sidewalls of the gate trenches 156T, but the channel region 150 may not be on the sidewalls of the gate trenches 156T.

Referring to FIGS. 10B and 10C, a plurality of gate junction regions 180 may be formed in the semiconductor layer structure 120 by implanting p-type dopant ions into the gate trenches 156T (e.g., into bottoms of the gate trenches 156T). In some embodiments, the same mask pattern 122 used to form the gate trenches 156T may be used to form the gate junction regions 180. In other embodiments, the mask pattern 122 may be removed after forming the gate trenches 156T, a new mask layer may be formed on an upper surface of the semiconductor layer structure 120, and the new mask layer may be patterned to provide a mask pattern that exposes selected portions of the semiconductor layer structure 120 where the gate junction regions 180 are to be formed. The gate junction regions 180 may be moderately-doped p-type (p) regions and may have a doping concentration of, for example, 5×10¹⁶ to 1×10¹⁹ dopants/cm³. For example, the gate junction regions 180 may extend adjacent the source region 160, the channel region 150, and the drift region 140. After forming the gate junction regions 180, the gate trenches 156T may be spaced apart from the channel region 150. For example, portions of the channel region 150 underneath the gate trenches 156T may be converted into the gate junction regions 180.

In some embodiments, termination structures 184 may be concurrently formed in the semiconductor layer structure 120 by implanting the p-type dopant ions into portions of the semiconductor layer structure 120 in the termination region 106 that are exposed by the mask pattern 122. In other words, the gate junction regions 180 in the active region 102 and the termination structures 184 in the termination region 106 may be formed in a same ion implantation step by implanting p-type dopant ions into the semiconductor layer structure 120, which streamlines a process for formation of the termination structures 184 and reduces variations in the locations, shapes, and doping profiles of the termination structures 184. The termination structures 184 and the gate junction regions 180 may have a same doping concentration.

As shown in FIG. 10C, portions of the semiconductor layer structure 120 (e.g., portions of the p-type region 188) in the termination region 106 may be etched in the same etching step that is used to form the gate trenches 156T in the active region 102, thereby forming recesses in the upper surface of the semiconductor layer structure 120 in the termination region 106. The termination structures 184 may be formed by implanting p-type dopant ions into the recesses (e.g., into bottoms of the recesses) in the same ion implantation step that is used to form the gate junction regions 180. Although not shown in FIG. 10C, in other embodiments, the termination region 106 (e.g., the p-type region 188) may not be etched during the etching step that is used to form the gate trenches 156T, and the termination structures 184 may be formed by implanting p-type dopant ions into an upper surface of the semiconductor layer structure 120 in the termination region 106 in the same ion implantation step that is used to form the gate junction regions 180. In this case, upper surfaces of the termination structures 184 may be substantially coplanar with an upper surface of the semiconductor layer structure 120 in the active region 102 (e.g., may be coplanar with upper surfaces of the source regions 160).

In some embodiments, a gate well region 170 may also be concurrently formed in the semiconductor layer structure 120 by implanting p-type dopant ions into portions of the semiconductor layer structure 120 in the gate region 104 that are exposed by the mask pattern 122. In this case, the gate well region 170 and the gate junction regions 180 may have a same doping concentration. In other embodiments, the gate well region 170 may be formed in a separate ion implantation step so that doping concentrations of the gate well region 170 and the gate junction regions 180 may be set at optimum levels.

The gate junction regions 180 may extend in the depth direction D in the semiconductor layer structure 120 through the source and channel regions 160 and 150 into the drift region 140. Although not shown in FIGS. 10B and 10C, in other embodiments, the p-type dopant ions used to form the gate junction regions 180 may be implanted at lower energies so that the gate junction regions 180 extend through the source region 160 into the channel region 150 but do not reach the drift region 140. In this case, the gate junction regions 180 may extend in a depth direction D in the semiconductor layer structure 120 through the source region 160 into the channel region 150, while being spaced apart from the drift region 140 in the depth direction D (e.g., see the gate junction regions 180 in FIG. 6C).

While not specifically shown in FIGS. 10B and 10C, in some embodiments, the p-type dopant concentration may be increased in an upper portion of each gate junction region 180 to form a gate contact region in the upper portion of each gate junction region 180, and hence an upper portion of each gate junction region 180 may be more heavily doped than the lower portion thereof (e.g., see the gate contact regions 182 in FIG. 6A).

In some embodiments, a random ion implantation process may be performed to form the gate junction regions 180. For example, p-type dopant ions may be implanted at an angle of 90° with respect to an upper surface of the semiconductor layer structure 120 (i.e., vertically) during the random ion implantation process. The random ion implantation process may result in the gate junction regions 180 spreading out laterally, and the amount of lateral spread may increase with increasing depth in the semiconductor layer structure 120. The gate junction regions 180 may thus have widths that monotonically change such that they increase in the transverse direction T with increasing depth in the semiconductor layer structure 120 in the depth direction D. Although not shown in FIGS. 10B and 10C, in other embodiments, a channeled ion implantation process may be performed to form the gate junction regions 180, and the gate junction regions 180 may have sidewalls that angle inwardly with increasing depth in the semiconductor layer structure 120 in the depth direction D. In this case, the gate junction regions 180 may have widths that monotonically change such that they decrease in the transverse direction T with increasing depth in the semiconductor layer structure 120 in the depth direction D (e.g., see the gate junction regions 180 in FIG. 7A).

Referring back to FIGS. 6A and 6B, a plurality of gate electrodes 114 may be formed in the gate trenches 156T, respectively, in the active region 102. The gate electrodes 114 may be in contact with and electrically connected to the gate junction regions 180, respectively. In other embodiments, the gate electrodes 114 may be in contact with gate contact regions 182 (if provided), respectively. Gate insulating patterns 186 may be formed in the gate trenches 156T on the gate electrodes 114 (e.g., on the metal portions 114M or on the metal silicide portions 114S if the metal portions 114M are not provided) to cover each gate electrode 114. A source contact 190 may be formed on the source regions 160 and the gate insulating patterns 186. A drain pad 192 (e.g., a metal drain pad) may be formed on the bottom side of the power JFET 100 (e.g., on a lower surface of the substrate 130 opposite the drift region 140). Accordingly, a partial trench gate power JFET 100 may be formed.

While the semiconductor devices discussed above are n-type devices, it will be appreciated that in p-type devices the conductivity of each n-type and p-type region would be reversed. Thus, it will be appreciated that while n-type JFETs are discussed above by way of example, any of the JFETs disclosed herein may alternatively be implemented as a p-type JFET. Thus, it will be appreciated that the present disclosure covers both n-channel and p-channel devices for each different semiconductor device. Moreover, while the above-described power semiconductor devices and the other devices described herein may be described as being silicon carbide-based semiconductor devices, it will be appreciated that embodiments of the present disclosure are not limited thereto. Instead, the semiconductor devices may include any wide bandgap semiconductor that is suitable for use in power semiconductor devices including, for example, gallium nitride-based semiconductor devices, gallium nitride-based semiconductor devices and II-VI compound semiconductor devices.

Example embodiments of the present disclosure are primarily described above with respect to cross-sectional views. It will be appreciated that in each of the depicted embodiments of the present disclosure, the gate junction regions, the gate contact regions, the gate trenches, etc. may be elongated structures that extend continuously into the page in the figures across the active region of the semiconductor devices. However, it will also be appreciated that the gate junction regions and/or the gate contact regions may instead be segmented structures in other embodiments that have sections removed so that these structures do not extend continuously into the pages in the figures, but instead are structures with multiple collinear segments extending into the page.

Example embodiments of the present disclosure have been described above with reference to the accompanying drawings, in which embodiments of the present disclosure are shown. The present disclosure may, however, be embodied in many different forms and should not be construed as limited to the example embodiments set forth herein. Rather, these embodiments are provided so that this disclosure will be thorough and complete, and will fully convey the scope thereof to those skilled in the art. In the drawings, the size and relative sizes of layers and regions may be exaggerated for clarity. Additionally, variations from the shapes of the illustrations as a result, for example, of manufacturing techniques and/or tolerances, may occur.

It will be understood that when an element or layer is referred to as being “on”, “connected to” or “coupled to” another element or layer, it can be directly on, connected to or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items, the term “plurality” means two or more, and the term “substantially” means within +/−10%. Like reference numbers refer to like elements throughout, except where expressly noted.

Some embodiments of the present disclosure are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

It will be understood that although the terms first and second may be used herein to describe various regions, layers and/or elements, these regions, layers and/or elements should not be limited by these terms. These terms are only used to distinguish one region, layer or element from another region, layer or element. Thus, a first region, layer or element could also be termed a second region, layer or element, and similarly, a second region, layer or element could also be termed a first region, layer or element without departing from the scope of the present disclosure.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on the “upper” side of the other elements. The exemplary term “lower” can, therefore, encompass both an orientation of “lower” and “upper,” depending on the particular orientation of the figure. Similarly, if the device in one of the figures is turned over, elements described as “below”, “beneath” or “underneath” other elements would then be oriented “above” the other elements. The exemplary terms “below”, “beneath” or “underneath” can, therefore, encompass both an orientation of above and below.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises,” “comprising,” “includes” and/or “including,” when used herein specify the presence of stated features, elements, components, and/or groups but do not preclude the presence or addition of one or more other features, elements, components, and/or groups thereof.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present disclosure may include additional and/or intervening layers, structures, or elements, and/or particular layers, structures, or elements may be deleted. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. Therefore, it is to be understood that the foregoing is illustrative of the present disclosure and is not to be construed as limited to the specific embodiments disclosed, and that modifications to the disclosed embodiments, as well as other embodiments, are intended to be included within the scope of the appended claims. The present disclosure is defined by the following claims, with equivalents of the claims to be included therein.

1. A semiconductor device, comprising:
a semiconductor layer structure that comprises a drift region having a first conductivity type and a gate junction region having a second conductivity type; and
a gate trench in the semiconductor layer structure,
wherein at least a portion of the gate junction region that is on a sidewall of the gate trench has a tapered shape in a cross-sectional view.

2. The semiconductor device of claim 1, wherein the gate junction region extends underneath the gate trench.

3-4. (canceled)

5. The semiconductor device of claim 1, wherein the semiconductor layer structure further comprises a gate contact region underneath the gate trench and having the second conductivity type.

6. The semiconductor device of claim 5, wherein the gate contact region has a higher second conductivity type doping concentration than the gate junction region.

7. The semiconductor device of claim 5, wherein the gate junction region is on sidewalls of the gate contact region.

8. The semiconductor device of claim 7, wherein the gate junction region extends underneath the gate contact region.

9. The semiconductor device of claim 5, further comprising a gate electrode in the gate trench and on the gate contact region.

10. The semiconductor device of claim 9, wherein the gate contact region electrically connects the gate electrode to the gate junction region.

11-12. (canceled)

13. The semiconductor device of claim 1, wherein the semiconductor layer structure further comprises a channel region having the first conductivity type on the drift region and a source region having the first conductivity type on the channel region.

14. The semiconductor device of claim 13, wherein an upper portion of the channel region has a higher first conductivity type doping concentration than a lower portion of the channel region.

15. The semiconductor device of claim 13, wherein the gate junction region is a first gate junction region,
wherein the semiconductor layer structure further comprises a second gate junction region adjacent the first gate junction region, and
wherein at least a portion of the channel region between the first gate junction region and the second gate junction region has a width that decreases with increasing depth in the semiconductor layer structure.

16. (canceled)

17. The semiconductor device of claim 1, wherein the semiconductor device comprises a silicon carbide-based junction field effect transistor (“JFET”).

18. A semiconductor device, comprising:
a semiconductor layer structure that comprises a drift region having a first conductivity type and a gate junction region having a second conductivity type; and
a gate trench in the semiconductor layer structure,
wherein a width of a portion of the gate junction region that extends along a sidewall of the gate trench monotonically changes with increasing depth in the semiconductor layer structure.

19. The semiconductor device of claim 18, wherein the width of the portion of the gate junction region increases with increasing depth in the semiconductor layer structure.

20. The semiconductor device of claim 18, wherein the width of the portion of the gate junction region decreases with increasing depth in the semiconductor layer structure.

21. The semiconductor device of claim 18, wherein at least a portion of the gate junction region comprises sidewalls that angle inwardly with increasing depth in the semiconductor layer structure.

22. (canceled)

23. The semiconductor device of claim 18, wherein the semiconductor layer structure further comprises a gate contact region underneath the gate trench and having the second conductivity type.

24. The semiconductor device of claim 23, wherein the gate contact region has a higher second conductivity type doping concentration than the gate junction region.

25. (canceled)

26. The semiconductor device of claim 23, further comprising a gate electrode in the gate trench and in contact with the gate contact region.

27. The semiconductor device of claim 18, wherein the semiconductor layer structure further comprises a channel region having the first conductivity type on the drift region and a source region having the first conductivity type on the channel region,
wherein the source region and the channel region are on the sidewall of the gate trench, and
wherein the channel region is on a sidewall of the gate junction region.

28-30. (canceled)

31. The semiconductor device of claim 27, wherein the gate junction region is a first gate junction region,
wherein the semiconductor layer structure further comprises a second gate junction region adjacent the first gate junction region, and
wherein at least a portion of the channel region between the first gate junction region and the second gate junction region has a width that increases with increasing depth in the semiconductor layer structure.

32. The semiconductor device of claim 18, wherein the semiconductor layer structure comprises an active region comprising the gate junction region and a termination region comprising at least one termination structure, and
wherein the gate junction region and the at least one termination structure have a same doping concentration.

33-34. (canceled)

35. A junction field effect transistor (“JFET”), comprising a semiconductor layer structure that comprises:
a drift region having a first conductivity type;
a channel region on the drift region and having the first conductivity type;
a source region on the channel region and having the first conductivity type; and
a gate junction region comprising a sidewall that contacts the source region, the gate junction region having a second conductivity type.

36. The JFET of claim 35, wherein at least a portion of the gate junction region has a width that monotonically changes with increasing depth in the semiconductor layer structure.

37-38. (canceled)

39. The JFET of claim 35, wherein the channel region extends underneath the gate junction region.

40. The JFET of claim 35, wherein the drift region contacts the sidewall of the gate junction region.

41. The JFET of claim 35, further comprising a gate electrode on an upper surface of the semiconductor layer structure and on the gate junction region.

42. The JFET of claim 35, wherein an upper surface of the gate junction region is substantially coplanar with an upper surface of the source region.

43. The JFET of claim 35, further comprising a gate trench in the semiconductor layer structure and on the gate junction region.

44. (canceled)

45. The JFET of claim 43, wherein the source region is on a sidewall of the gate trench, and
wherein the channel region is not on the sidewall of the gate trench.

46-91. (canceled)
